(19) United States
(12) Patent Application Publication
(10) Pub. No.: US 2025/0212602 A1
(43) Pub. Date: Jun. 26, 2025

(54) MANUFACTURING METHOD OF DISPLAY DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Hidekazu MIYAIRI, Hadano, Kanagawa (JP); Ryota HODO, Atsugi, Kanagawa (JP)

(21) Appl. No.: 18/849,412

(22) PCT Filed: Mar. 13, 2023
(86) PCT No.: PCT/IB2023/052372

§ 371 Date: Sep. 20, 2024

(30) Foreign Application Priority Data
Mar. 25, 2022 (JP) 2022-049825
Mar. 25, 2022 (JP) 2022-049834

(51) Int. Cl. H10K 59/12; H10K 59/122

(52) U.S. Cl. CPC H10K 59/1201; H10K 59/122

(57) ABSTRACT

A display device with high resolution is provided. A first insulating layer covering an end portion of a pixel electrode is formed; a first layer overlapping with part of the first insulating layer and a first pixel electrode is formed and another part of the first insulating layer and a second pixel electrode are exposed; a second layer overlapping with the another part of the first insulating layer and the second pixel electrode is formed; a second insulating layer covering the first insulating layer is formed; a resin layer overlapping with the first insulating layer is formed over the second insulating layer; and a common electrode is formed to cover the first film, the second film, and the resin layer. The first film contains a first light-emitting material that emits first light, and the second film contains a second light-emitting material that emits second light of a color different from that of the first light.

### TECHNICAL FIELD

One embodiment of the present invention relates to a display device. One embodiment of the present invention relates to a manufacturing method of a display device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher-resolution display panels have been required. Examples of devices that require high-resolution display panels include a smartphone, a tablet terminal, and a laptop computer. In addition, higher resolution has been required for a stationary display device such as a television device or a monitor device with an increase in definition. Furthermore, a device for virtual reality (VR) or augmented reality (AR) is given as an example of a device that is required to have the highest resolution.

In addition, examples of a display device that can be employed for a display panel include, typically, a liquid crystal display device, a light-emitting device including a light-emitting element such as an organic EL (Electro Luminescence) element or a light-emitting diode (LED), electronic paper performing display by an electrophoretic method or the like, and the like.

For example, the basic structure of an organic EL element is a structure where a layer containing a light-emitting organic compound is provided between a pair of electrodes. By voltage application to this element, light emission can be obtained from the light-emitting organic compound. A display device using such an organic EL element does not need a backlight that is necessary for a liquid crystal display device or the like; thus, a thin, lightweight, high-contrast, and low-power-consumption display device can be achieved. Patent Document 1, for example, discloses an example of a display device using an organic EL element.

### REFERENCE

### Patent Document

[Patent Document 1] Japanese Published Patent Application No. 2002-324673

### SUMMARY OF THE INVENTION

### Problems to be Solved by the Invention

An object of one embodiment of the present invention is to provide a display device that can easily achieve a higher resolution. Another object is to provide a display device with high display quality. Another object is to provide a display device with high contrast. Another object is to provide a display device with high color reproducibility. Another object is to provide a display device with a high aperture ratio. Another object is to provide a highly reliable display device.

Another object of one embodiment of the present invention is to provide a display device having a novel structure or a manufacturing method of the display device. Another object of one embodiment of the present invention is to provide a manufacturing method of the above-described display device with high yield. Another object of one embodiment of the present invention is to at least reduce at least one of problems of conventional technique.

Note that the description of these objects does not preclude the existence of other objects. In one embodiment of the present invention, there is no need to achieve all these objects. Note that objects other than these can be derived from the description of the specification, the drawings, the claims, and the like.

### Means for Solving the Problems

One embodiment of the present invention is a manufacturing method of a display device including the following steps. That is, a first pixel electrode and a second pixel electrode are formed; a first insulating layer covering an end portion of the first pixel electrode and an end portion of the second pixel electrode and overlapping with a region sandwiched between the first pixel electrode and the second pixel electrode is formed; a first film is formed over the first pixel electrode, the second pixel electrode, and the first insulating layer; a first sacrificial film is formed over the first film; part of the first film and part of the first sacrificial film are removed to form a first layer and a first sacrificial layer overlapping with part of the first insulating layer and the first pixel electrode and to expose another part of the first insulating layer and the second pixel electrode; a second film is formed over the first sacrificial layer, the second pixel electrode, and the first insulating layer; a second sacrificial film is formed over the second film; part of the second film and part of the second sacrificial film are removed to form a second layer and a second sacrificial layer overlapping with the another part of the first insulating layer and the second pixel electrode and to expose the first sacrificial layer; a second insulating layer covering the first sacrificial layer, the second sacrificial layer, and the first insulating layer is formed; a resin layer overlapping with the first insulating layer is formed over the second insulating layer; part of the first sacrificial layer, part of the second sacrificial layer, and part of the second insulating layer are removed by etching using the resin layer as a mask to expose the first film and the second film; and a common electrode is formed to cover the first film, the second film, and the resin layer. The first film contains a first light-emitting material that emits first light, and the second film contains a second light-emitting material that emits second light of a color different from that of the first light.

Another embodiment of the present invention is a manufacturing method of a display device including the following steps. That is, a first pixel electrode and a second pixel electrode are formed; a first insulating layer covering an end portion of the first pixel electrode and an end portion of the second pixel electrode and overlapping with a region sandwiched between the first pixel electrode and the second pixel electrode is formed; a first film is formed over the first pixel electrode, the second pixel electrode, and the first insulating layer; a first sacrificial film is formed over the first film; part of the first film and part of the first sacrificial film are removed to form a first layer and a first sacrificial layer overlapping with part of the first insulating layer and the first pixel electrode and to expose another part of the first insulating layer and the second pixel electrode; a second film is formed over the first sacrificial layer, the second pixel electrode, and the first insulating layer; a second sacrificial film is formed over the second film; part of the second film and part of the second sacrificial film are removed to form a second layer and a second sacrificial layer overlapping with the another part of the first insulating layer and the second pixel electrode and to expose the first sacrificial layer; a second insulating layer covering the first sacrificial layer, the second sacrificial layer, and the first insulating layer is formed; a resin layer overlapping with the first insulating layer is formed over the second insulating layer; part of the second insulating layer is removed by etching using the resin layer as a mask and, after the removing, the first sacrificial layer and the second sacrificial layer are thinned; heat treatment is performed; part of the first sacrificial layer and part of the second sacrificial layer are removed by etching using the resin layer as a mask to expose the first film and the second film; and a common electrode is formed to cover the first film, the second film, and the resin layer. The first film contains a first light-emitting material that emits first light, and the second film contains a second light-emitting material that emits second light of a color different from that of the first light.

In the above, the first insulating layer is preferably formed using a photosensitive organic resin. In this case, the first insulating layer preferably contains one or more selected from an acrylic resin, a polyimide resin, an epoxy resin, a polyamide resin, a polyimide-amide resin, a siloxane resin, a benzocyclobutene-based resin, a phenol resin, and a precursor of any of these resins.

Alternatively, in the above, the first insulating layer is preferably formed using an inorganic insulating material. In this case, the first insulating layer preferably contains one or more selected from silicon oxide, silicon oxynitride, silicon nitride oxide, silicon nitride, aluminum oxide, aluminum oxynitride, and hafnium oxide.

In the above, the heat treatment is preferably performed at a temperature of higher than or equal to 50° C. and lower than or equal to 200° C.

In the above, the resin layer is preferably changed in shape by the heat treatment.

In any of the above, the first sacrificial film, the second sacrificial film, and the second insulating layer are preferably etched by wet etching.

In any of the above, the first sacrificial film, the second sacrificial film, and the second insulating layer are preferably formed by an atomic layer deposition method.

In any of the above, the first sacrificial film, the second sacrificial film, and the second insulating layer preferably contain aluminum oxide.

In any of the above, it is preferable that the first light be blue and the second light be green or red.

### Effect of the Invention

According to one embodiment of the present invention, a display device that easily achieves higher resolution can be provided. Alternatively, a display device with high display quality can be provided. Alternatively, a display device with high contrast can be provided. Alternatively, a display device with high color reproducibility can be provided. Alternatively, a display device with a high aperture ratio can be provided. Alternatively, a highly reliable display device can be provided.

According to one embodiment of the present invention, a display device having a novel structure or a manufacturing method of the display device can be provided. Alternatively, a manufacturing method of the above-described display device with high yield can be provided. One embodiment of the present invention can at least reduce at least one of problems of the conventional technique.

Note that the description of these effects does not preclude the existence of other effects. Note that one embodiment of the present invention does not need to have all these effects. Note that effects other than these can be derived from the description of the specification, the drawings, the claims, and the like.

### BRIEF DESCRIPTION OF THE DRAWINGS

FIG. 1A to FIG. 1C are diagrams each illustrating a structure example of a display device.

FIG. 2A to FIG. 2E are diagrams each illustrating a structure example of a display device.

FIG. 3A to FIG. 3C are diagrams each illustrating a structure example of a display device.

FIG. 4 is a diagram illustrating a structure example of a display device.

FIG. 5A to FIG. 5C are diagrams each illustrating a structure example of a display device.

FIG. 6 is a diagram illustrating a structure example of a display device.

FIG. 7A and FIG. 7B are diagrams each illustrating a structure example of a display device.

FIG. 8 is a diagram illustrating a structure example of a display device.

FIG. 9A to FIG. 9C are diagrams each illustrating a structure example of a display device.

FIG. 10A to FIG. 10C are diagrams each illustrating a structure example of a display device.

FIG. 11A to FIG. 11G are diagrams each illustrating a manufacturing method of a display device.

FIG. 12A to FIG. 12F are diagrams each illustrating a manufacturing method of a display device.

FIG. 13A to FIG. 13F are diagrams each illustrating a manufacturing method of a display device.

FIG. 14A to FIG. 14G are diagrams each illustrating a manufacturing method of a display device.

FIG. 15A to FIG. 15F are diagrams each illustrating a manufacturing method of a display device.

FIG. 16A to FIG. 16F are diagrams each illustrating a manufacturing method of a display device.

FIG. 17A to FIG. 17G are diagrams each illustrating an example of a pixel.

FIG. 18A to FIG. 18K are diagrams each illustrating an example of a pixel.

FIG. 19A and FIG. 19B are diagrams each illustrating a structure example of a display device.

FIG. 20 is a diagram illustrating a structure example of a display device.

FIG. 21 is a diagram illustrating a structure example of a display device.

FIG. 22 is a diagram illustrating a structure example of a display device.

FIG. 23 is a diagram illustrating a structure example of a display device.

FIG. 24 is a diagram illustrating a structure example of a display device.

FIG. 25 is a diagram illustrating a structure example of a display device.

FIG. 26 is a diagram illustrating a structure example of a display device.

FIG. 27 is a diagram illustrating a structure example of a display device.

FIG. 28 is a diagram illustrating a structure example of a display device.

FIG. 29 is a diagram illustrating a structure example of a display device.

FIG. 30 is a diagram illustrating a structure example of a display device.

FIG. 31 is a diagram illustrating a structure example of a display device.

FIG. 32A to FIG. 32F are diagrams each illustrating a structure example of a light-emitting device.

FIG. 33A to FIG. 33C are diagrams each illustrating a structure example of a light-emitting device.

FIG. 34A to FIG. 34D are diagrams each illustrating a structure example of an electronic device.

FIG. 35A to FIG. 35F are diagrams each illustrating a structure example of an electronic device.

FIG. 36A to FIG. 36G are diagrams each illustrating a structure example of an electronic device.

### MODE FOR CARRYING OUT THE INVENTION

Embodiments are described below with reference to the drawings. Note that the embodiments can be implemented with many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

Note that in each drawing described in this specification, the size, the layer thickness, or the region of each component is exaggerated for clarity in some cases. Thus, they are not limited to the illustrated scale.

Note that in this specification and the like, ordinal numbers such as “first” and “second” are used in order to avoid confusion among components and do not limit the number.

Note that in this specification and the like, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “top surface shapes are substantially the same”. Note that in this specification and the like, a top surface shape of a component means the contour shape of the component in a plan view. A plan view means that the component is observed from a normal direction of a formation surface of the component or a surface of a support (e.g., a substrate) where the component is formed.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or formation order) of a stacked body or the like is described, even in the case where a surface on which the stacked body is provided (e.g., a formation surface, a support surface, an adhesion surface, or a planar surface) is positioned above the stacked body in the drawings, the direction and the opposite direction are expressed using “under” and “over”, respectively, in some cases.

In this specification and the like, the term “film” and the term “layer” can be interchanged with each other. For example, in some cases, the term “conductive layer” and the term “insulating layer” can be interchanged with the term “conductive film” and the term “insulating film”, respectively.

### EMBODIMENT 1

In this embodiment, a structure example and an example of a manufacturing method of a display device of one embodiment of the present invention will be described.

One embodiment of the present invention is a display device including a light-emitting element (also referred to as a light-emitting device). The display device includes two or more light-emitting elements that emit light of different colors. The light-emitting elements each include a pair of electrodes and an EL layer therebetween. The light-emitting elements are preferably organic EL elements (organic electroluminescent elements). Two or more light-emitting elements emitting different colors include respective EL layers containing different materials. For example, three kinds of light-emitting elements emitting red (R), green (G), and blue (B) light are included, whereby a full-color display device can be obtained.

As a way of forming some or all of EL layers separately between light-emitting elements of different emission colors, an evaporation method using a shadow mask such as a metal mask is known. However, this method causes a deviation from the designed shape and position of an island-shaped organic film due to various influences such as the low accuracy of the metal mask, the positional deviation between the metal mask and a substrate, a warp of the metal mask, and the expansion of outline of the deposited film caused by vapor-scattering or the like; accordingly, it is difficult to achieve high resolution and a high aperture ratio of the display device. Thus, a measure has been taken for pseudo improvement in resolution (also referred to pixel density) by employing a unique pixel arrangement method such as a PenTile arrangement.

In one embodiment of the present invention, fine patterning of an EL layer is performed without a shadow mask such as a metal mask. This can achieve a display device with high resolution and a high aperture ratio, which has been difficult to achieve. Moreover, EL layers can be separately formed, enabling the display device to perform extremely clear display with high contrast and high display quality.

Here, a description is made on a case where EL layers in light-emitting elements of two colors are separately formed, for simplicity. First, between two pixel electrodes, a first insulating layer covering end portions of those pixel electrodes is provided. Providing the first insulating layer can improve step coverage with an EL film or the like deposited later and inhibit generation of deposition defects and processing defects.

Next, a stack of a first EL film and a first sacrificial film is formed to cover the two pixel electrodes and the first insulating layer. Next, a resist mask is formed over the first sacrificial film in a position overlapping with one pixel electrode (a first pixel electrode) and part of the first insulating layer. Then, part of the first sacrificial film and part of the first EL film that does not overlap with the resist mask are etched. Thus, part of the first EL film processed into a belt-like shape or an island shape (also referred to as a first EL layer) can be formed over the first pixel electrode and the first insulating layer, and part of the first sacrificial film (also referred to as a first sacrificial layer) can be formed thereover.

Next, a stack of a second EL film and a second sacrificial film is formed. Then, a resist mask is formed in a position overlapping with a second pixel electrode and another part of the first insulating layer. Then, part of the second sacrificial film and part of the second EL film are etched in a manner similar to the above. As a result, a state in which the first EL layer and the first sacrificial layer are provided over the first pixel electrode and the part of the first insulating layer, and a second EL layer and a second sacrificial layer are provided over the second pixel electrode and the another part of the first insulating layer is obtained. In this manner, the first EL layer and the second EL layer can be formed separately.

Next, a protective layer (a second insulating layer) is formed to cover the first sacrificial film and the second sacrificial film. At this time, the protective layer is provided to cover a side surface of the first EL layer and a side surface of the second EL layer. Next, a resin layer is formed over the second insulating layer in a region sandwiched between the first EL layer and the second EL layer. The protective layer can prevent the first EL layer and the second EL layer from being damaged in a step of forming the resin layer. Next, the first sacrificial layer, the second sacrificial layer, and the protective layer are etched using the resin layer as a mask to expose part of the first EL layer and part of the second EL layer, and a common electrode is formed. The resin layer has a function of improving step coverage with the common electrode formed later. Thus, light-emitting elements of two colors can be separately formed.

Furthermore, by repeating the above-described steps, EL layers in light-emitting elements of three or more colors can be separately formed; accordingly, a display device including light-emitting elements of three colors or four or more colors can be achieved.

The insulating layer provided between the two adjacent pixel electrodes covers end portions of the pixel electrodes. A region positioned on the pixel electrode and covered with the insulating layer does not function as a light-emitting region of the light-emitting element; therefore, the narrower the region where the insulating layer and the pixel electrode overlap is, the higher an effective light-emitting area ratio i.e., an aperture ratio of the display device can be.

The end portions of the EL layers are positioned over the insulating layer. At this time, end portions (side surfaces) of two EL layers are provided to face each other. When the distance between the two EL layers is smaller, the width of the insulating layer can be smaller and thus the aperture ratio of the display device can be increased.

More specific examples are described below with reference to drawings.

### Structure Example 1

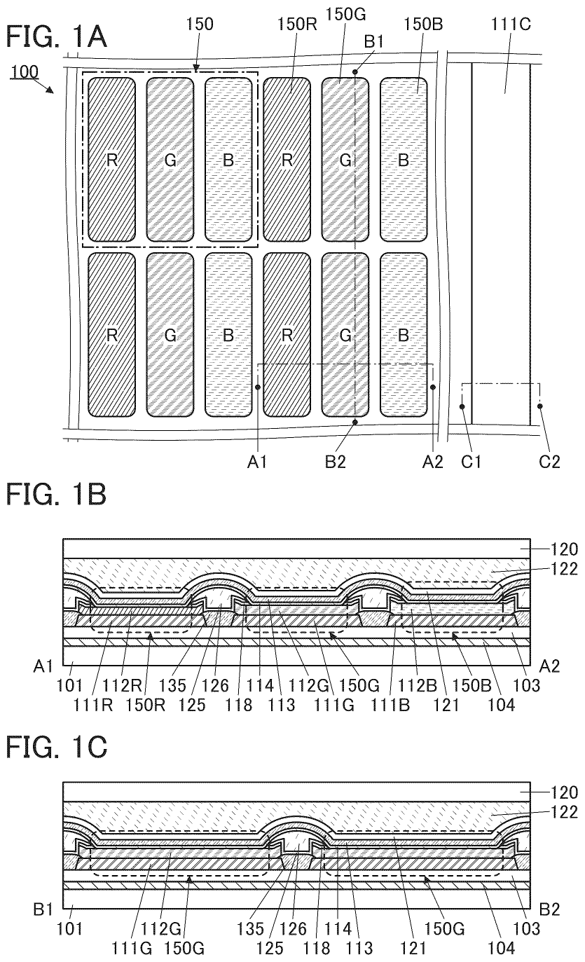

FIG. 1A illustrates a schematic top view of a display device 100. The display device 100 includes a plurality of pixels 150 arranged in a matrix. The pixels 150 include a plurality of light-emitting elements 150R exhibiting red, a plurality of light-emitting elements 150G exhibiting green, and a plurality of light-emitting elements 150B exhibiting blue. In FIG. 1A, light-emitting regions of the light-emitting elements are denoted by R, G, and B to easily differentiate the light-emitting elements.

Hereinafter, in the description common to the components that are distinguished by alphabets, such as the light-emitting element 150R, the light-emitting element 150G, and the light-emitting element 150B, reference numerals without alphabets are sometimes used to avoid duplication.

FIG. 1A illustrates what is called a stripe arrangement, in which light-emitting elements of the same color are arranged in one direction. Note that the arrangement method of the light-emitting elements is not limited thereto; another arrangement method such as a delta arrangement or a zigzag arrangement may be used or a PenTile arrangement may also be used.

As the light-emitting element 150R, the light-emitting element 150G, and the light-emitting element 150B, an OLED (Organic Light Emitting Diode), a QLED (Quantum-dot Light Emitting Diode), or the like is preferably used. Examples of a light-emitting substance (also referred to as a light-emitting material) contained in the light-emitting element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). As the light-emitting substance contained in the light-emitting element, not only an organic compound but also an inorganic compound (a quantum dot material or the like) can be used.

FIG. 1B is a schematic cross-sectional view taken along the dashed-dotted line A1-A2 in FIG. 1A, and FIG. 1C is a schematic cross-sectional view taken along the dashed-dotted line B1-B2.

The display device 100 is provided with a functional layer 104 and an insulating layer 103 stacked over a substrate 101. The light-emitting element 150R, the light-emitting element 150G, the light-emitting element 150B, and the like are provided over the insulating layer 103. The substrate 101 is bonded to a substrate 120 with an adhesive layer 122 positioned therebetween.

The functional layer 104 includes a circuit composed of a transistor, a diode, a wiring, a capacitor, a resistor, and the like, for example. Specifically, a pixel circuit for controlling light emission of the light-emitting element 150R, the light-emitting element 150G, and the light-emitting element 150B is provided. In addition to the pixel circuit, at least part of a gate line driver circuit (a gate driver), a source line driver circuit (a source driver), an arithmetic circuit, a memory circuit, or the like may be provided in the functional layer.

The insulating layer 103 functions as an interlayer insulating film. The insulating layer 103 can be formed of an organic insulating film, an inorganic insulating film, or both of them. Although not described here, a plurality of openings are provided in the insulating layer 103, and each of the light-emitting element 150R, the light-emitting element 150G, and the light-emitting element 150B is electrically connected to the functional layer 104 through the openings.

FIG. 1B illustrates cross sections of the light-emitting element 150R, the light-emitting element 150G, and the light-emitting element 150B. The light-emitting element 150R includes a pixel electrode 111R, an EL layer 112R, a common layer 114, and a common electrode 113. The light-emitting element 150G includes a pixel electrode 111G, an EL layer 112G, the common layer 114, and the common electrode 113. The light-emitting element 150B includes a pixel electrode 111B, an EL layer 112B, the common layer 114, and the common electrode 113. The common layer 114 and the common electrode 113 are provided to be shared by the light-emitting element 150R, the light-emitting element 150G, and the light-emitting element 150B.

The EL layer 112R included in the light-emitting element 150R contains at least a light-emitting organic compound that emits red light. The EL layer 112G included in the light-emitting element 150G contains at least a light-emitting organic compound that emits green light. The EL layer 112B included in the light-emitting element 150B contains at least a light-emitting organic compound that emits blue light.

The EL layer 112R, the EL layer 112G, and the EL layer 112B may each include one or more of an electron-injection layer, an electron-transport layer, a hole-injection layer, and a hole-transport layer in addition to a layer containing a light-emitting organic compound (the light-emitting layer). The common layer 114 does not necessarily include the light-emitting layer. For example, the common layer 114 includes one or more of an electron-injection layer, an electron-transport layer, a hole-injection layer, and a hole-transport layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a visible-light-transmitting property is used for either the pixel electrodes or the common electrode 113, and a conductive film having a reflective property is used for the other. When the pixel electrodes have a light-transmitting property and the common electrode 113 has a reflective property, a bottom-emission display device can be obtained. In contrast, when the pixel electrodes have a reflective property and the common electrode 113 has a light-transmitting property, a top-emission display device can be obtained. Note that when both the pixel electrodes and the common electrode 113 have a light-transmitting property, a dual-emission display device can be also obtained.

An insulating layer 135 is provided to cover end portions of the pixel electrode 111R, the pixel electrode 111G, and the pixel electrode 111B. The insulating layer 135 has a function of preventing a poor coverage of an EL layer 112 at an end portion of the pixel electrode 111. Therefore, the end portion of the insulating layer 135 positioned over the pixel electrode 111 preferably has a tapered shape. Note that in this specification and the like, an end portion of an object having a tapered shape indicates that the end portion of the object has a cross-sectional shape in which the angle between a surface of the object and a surface on which the object is formed is larger than 0° and smaller than 90° in a region of the end portion, preferably, larger than or equal to 5° and smaller than or equal to 70°, and the thickness continuously increases from the end portion.

The insulating layer 135 can prevent part of the insulating layer 103 from being exposed to etching and being thinned or removed in the etching treatment in the step of forming the EL layer 112R, the EL layer 112G, and the EL layer 112B. Since the functional layer 104 is provided below the insulating layer 103, when the insulating layer 103 is removed, a wiring, an electrode, or the like included in the functional layer 104 is exposed, which might cause a defect such as a short circuit. Thus, the insulating layer 135 also functions as a protective layer or a buffer layer for preventing the insulating layer 103 from being removed. Note that in some cases, the insulating layer 135 is partly thinned or partly removed due to etching treatment in the step of forming the EL layer 112R, the EL layer 112G, and the EL layer 112B, and any of the EL layer 112R, the EL layer 112G, and the EL layer 112B is in contact with part of the insulating layer 103.

The insulating layer 135 preferably contains an organic resin. Using an organic resin for the insulating layer 135 can increase adhesion between the insulating layer 135 and each of the EL layer 112R, the EL layer 112G, and the EL layer 112B, so that the manufacturing yield can be improved. In particular, in the case of processing EL layers by etching, it is preferable to use the insulating layer 135 having high adhesion with the EL layers, in which case a defect such as separation of the EL layers after etching can be decreased.

When an organic resin is used for the insulating layer 135, the insulating layer 135 can have a curved surface with a gentle change in curvature. Thus, coverage with a film formed over the insulating layer 135 can be improved.

Examples of the material that can be used for the insulating layer 135 include an acrylic resin, a polyimide resin, an epoxy resin, a polyamide resin, a polyimide-amide resin, a siloxane resin, a benzocyclobutene-based resin, a phenol resin, and precursors of these resins.

The EL layer 112R, the EL layer 112G, and the EL layer 112B each include a region in contact with the top surface of the pixel electrode and a region in contact with the surface of the insulating layer 135. The end portions of the EL layer 112R, the EL layer 112G, and the EL layer 112B are positioned over the insulating layer 135.

As illustrated in FIG. 1B, a gap is provided between two EL layers of light-emitting elements of different emission colors. In this manner, the EL layer 112R, the EL layer 112G, and the EL layer 112B are preferably provided with a gap so as not to be in contact with each other. This suitably prevents unintentional light emission from being caused by a current flowing through EL layers formed continuously between light-emitting elements of different emission colors. As a result, the contrast can be increased to achieve a display device with high display quality.

As illustrated in FIG. 1C, the EL layer 112G is formed to be divided also between adjacent pixels of the same color. Thus, unintended light leakage can be inhibited even between the pixels of the same color, so that a sharper image can be provided. Note that FIG. 1C illustrates a cross section of the light-emitting element 150G as an example; the light-emitting element 150R and the light-emitting element 150B can also have a similar shape.

Note that the EL layer 112R may be formed in a belt-like shape so that the EL layer 112R can be continuous. When the EL layer 112R and the like are formed in a belt-like shape, a space for dividing the layers is not needed and thus the area of a non-light-emitting region between the light-emitting elements can be reduced, resulting in a higher aperture ratio.

A protective layer 121 is provided over the common electrode 113 to cover the light-emitting element 150R, the light-emitting element 150G, and the light-emitting element 150B. The protective layer 121 has a function of preventing diffusion of impurities such as water into the light-emitting element from the above.

The protective layer 121 can have, for example, a single-layer structure or a stacked-layer structure including at least an inorganic insulating film. Examples of the inorganic insulating film include an oxide film or a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

For the protective layer 121, a stacked film of an inorganic insulating film and an organic insulating film can be used. For example, a structure in which an organic insulating film is sandwiched between a pair of inorganic insulating films is preferable. Furthermore, it is preferable that the organic insulating film function as a planarization film. With this structure, the top surface of the organic insulating film can be flat, and accordingly, coverage with the inorganic insulating film over the organic insulating film is improved, leading to an improvement in a barrier property. Moreover, a top surface of the protective layer 121 is flat, which is preferable because the influence of an uneven shape due to a lower structure can be reduced in the case where a component (e.g., a color filter, an electrode of a touch sensor, a lens array, or the like) is provided above the protective layer 121.

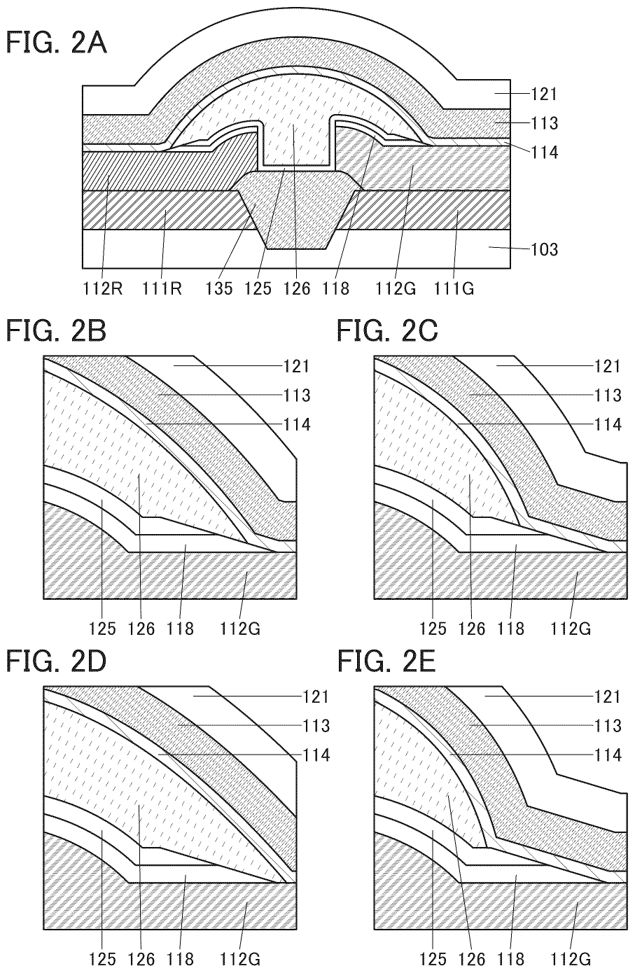

FIG. 2A is an example of an enlarged view of the pixel electrode 111R, the pixel electrode 111G, and a region sandwiched therebetween. Note that a similar structure can be provided between the pixel electrode 111R and the pixel electrode 111B, between the pixel electrode 111G and the pixel electrode 111B, and between the pixel electrodes of the same color. FIG. 2A and the like illustrate an example in which a portion of the insulating layer 103 that does not overlap with the pixel electrode 111R or the like is thinned.

The insulating layer 135 is provided to cover part of top surfaces and side surfaces of the end portions of each of the pixel electrode 111R and the pixel electrode 111G. End portions of the EL layer 112R and the EL layer 112G are positioned over the insulating layer 135. An insulating layer 125 is provided to cover part of top surfaces and side surfaces of each of the end portions of the EL layer 112R and the EL layer 112G. In a region sandwiched between the EL layer 112R and the EL layer 112G, the insulating layer 125 is provided to cover a top surface of the insulating layer 135.

A resin layer 126 is provided over the insulating layer 125. The resin layer 126 is provided to fill a depressed portion of a top surface of the insulating layer 125 positioned in a region sandwiched between the EL layer 112R and the EL layer 112G and functions as a planarization film. Furthermore, over the resin layer 126, the common layer 114, the common electrode 113, and the protective layer 121 are provided. Filling the depressed portion of the top surface of the insulating layer 125 with the resin layer 126 can prevent a phenomenon in which the common electrode 113 and the like is divided by a step (such a phenomenon is also referred to as disconnection) from occurring and the common electrode 113 over the EL layer 112 from being insulated. The resin layer 126 can also be referred to as LFP (also referred to as Local Filling Planarization).

Here, when the EL layer 112R and the like and the resin layer 126 are in contact with each other, the EL layer 112R and the like might be dissolved by an organic solvent or the like used at the time of forming the resin layer 126. Therefore, the insulating layer 125 is provided between the EL layer 112 and the resin layer 126 to protect the side surfaces of the EL layer 112. Furthermore, the insulating layer 125 can prevent the side surface of the EL layer 112 from being exposed to the air. Accordingly, a highly-reliable light-emitting element can be manufactured.

Here, an insulating layer 118 may be provided between the insulating layer 125 and a top surface of the EL layer 112R or the like. The insulating layer 118 is a remaining part of a protective layer (also referred to as a sacrificial layer or a mask layer) for protecting the EL layer 112R and the like during etching of the EL layer 112R and the like. For the insulating layer 118, a material that can be used for the insulating layer 125 can be used. It is particularly preferable to use the same material for the insulating layer 118 and the insulating layer 125 to facilitate processing.

The insulating layer 125 can be an insulating layer including an inorganic material. For the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is used for the insulating layer 125, it is possible to form the insulating layer 125 that has a small number of pinholes and has an excellent function of protecting the EL layer.

For the formation of the insulating layer 125, a sputtering method, a CVD method, a PLD method, an ALD method, or the like can be used. The insulating layer 125 is preferably formed by an ALD method that provides good coverage.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may contain a material that absorbs visible light. For example, the resin layer 126 itself may be made of a material that absorbs visible light, or the resin layer 126 may contain a pigment that absorbs visible light. For example, for the resin layer 126, it is possible to use a resin that can be used as a color filter that transmits red, blue, or green light and absorbs other light, a resin that contains carbon black as a pigment and functions as a black matrix, or the like.

Here, the insulating layer 125 and the insulating layer 118 can be formed by processing insulating films using the resin layer 126 as a mask. Therefore, depending on the processing conditions, the insulating layer 125 and the insulating layer 118 are sometimes formed such that their end portions protrude beyond an outline of the resin layer 126 in a plan view. In that case, portions of the insulating layer 125 and the insulating layer 118 protruding beyond the outline are preferably tapered. Thus, disconnection of the common layer 114 and the common electrode 113 covering portions of the insulating layer 125 and the insulating layer 118 protruding beyond the outline of the resin layer 126 can be inhibited.

The resin layer 126 can be changed in shape by various treatments in a manufacturing process of the display device in some cases. For example, after the resin layer 126 is formed, heat treatment, plasma treatment (e.g., surface treatment or dry etching treatment), wet treatment (e.g., cleaning or wet etching), exposure to a reduced-pressure atmosphere or a high-pressure atmosphere, and the like are performed. Treatment for changing the shape of the resin layer 126 is performed in the middle of a processing step for forming the insulating layer 125 and the insulating layer 118, for example, whereby the resin layer 126 can cover part of the end portions of the insulating layer 125 and the insulating layer 118.

FIG. 2B is an enlarged schematic cross-sectional view of end portions of the insulating layer 125, the insulating layer 118, and the resin layer 126 over the EL layer 112G and vicinity thereof in FIG. 2A. Note that in the case where the insulating layer 125 and the insulating layer 118 are formed using the same material, for example, a boundary (or an interface) between the insulating layer 125 and the insulating layer 118 is unclear in some cases even when being observed by cross-sectional observation. In that case, thicknesses of the insulating layer 125 and the insulating layer 118 can be estimated from thickness of an insulating layer in a region between the resin layer 126 and the EL layer 112 and the thickness of a resin layer in a region between the resin layer 126 and the insulating layer 135.

FIG. 2B illustrates an example in which the resin layer 126 covers the entire insulating layer 125 and part of an end portion of the insulating layer 118. The end portion of the insulating layer 118 has a sloped surface, part of which is covered with the resin layer 126, and the other part of which protrudes beyond the outline of the resin layer 126. A surface of the protruding portion of the insulating layer 118 is in contact with the common layer 114.

FIG. 2C illustrates an example in which the resin layer 126 covers part of an end portion of the insulating layer 125 and does not cover the end portion of the insulating layer 118. Like the insulating layer 118, the insulating layer 125 has the end portion with a sloped surface, part of which is covered with the resin layer 126, and the other part of which protrudes beyond the outline of the resin layer 126. The slope of the end portion of the insulating layer 118 protrudes beyond the outline of the resin layer 126. A surface of the protruding portion of the insulating layer 125 and a surface of the end portion of the insulating layer 118 are in contact with the common layer 114.

FIG. 2D illustrates an example in which the resin layer 126 covers the entire insulating layer 125 and the entire insulating layer 118. An end portion of the resin layer 126 crosses the end portions of the insulating layer 125 and the insulating layer 118 and is in contact with part of a top surface of the EL layer 112G. The common layer 114 is in contact with neither the insulating layer 125 nor the insulating layer 118, and the resin layer 126 is provided between the common layer 114 and the insulating layers 125 and 118.

FIG. 2E illustrates an example in which the end portion of the resin layer 126 is positioned inside the end portion of the insulating layer 125. The end portion of the insulating layer 125 and the end portion of the insulating layer 118 each have a sloped surface, and these slopes are not covered with the resin layer 126. Surfaces of the end portions of the insulating layer 125 and the insulating layer 118 are in contact with the common layer 114.

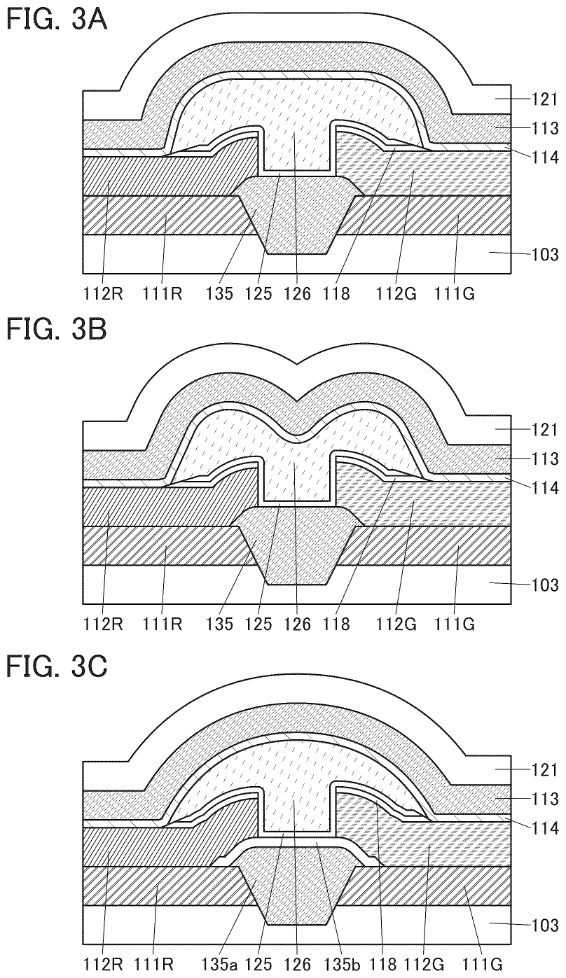

Although FIG. 2A and the like illustrate the case where a top surface of the resin layer 126 has a convex cross-sectional shape, one embodiment of the present invention is not limited thereto. For example, as illustrated in FIG. 3A, part of the top surface of the resin layer 126 may be flat, or as illustrated in FIG. 3B, part of the top surface of the resin layer 126 may be concave.

FIG. 3C illustrates an example in which the insulating layer 135 covering the end portion of the pixel electrode has a stacked-layer structure. FIG. 3C illustrates an example in which an insulating layer 135a covering the end portion of the pixel electrode and an insulating layer 135b covering the insulating layer 135a are included. The insulating layer 135b may include a region in contact with a top surface of the pixel electrode 111R and a top surface of the pixel electrode 111G. The above-described organic resin is preferably used for the insulating layer 135a. A material different from that for the insulating layer 135a is preferably used for the insulating layer 135b, and an inorganic insulating material is further preferably used. When the insulating layer 135b using the material different from that for the insulating layer 135a is provided to cover the insulating layer 135a in this manner, the insulating layer 135a containing the organic resin can be prevented from being etched at the time of etching for forming the EL layer 112R or the like.

Examples of inorganic insulating material that can be used for the insulating layer 135b include oxides or nitrides such as silicon oxide, silicon oxynitride, silicon nitride oxide, silicon nitride, aluminum oxide, aluminum oxynitride, and hafnium oxide. Yttrium oxide, zirconium oxide, gallium oxide, tantalum oxide, magnesium oxide, lanthanum oxide, cerium oxide, neodymium oxide, or the like may be used.

Here, FIG. 1A also illustrates a connection electrode 111C that is electrically connected to the common electrode 113. The connection electrode 111C is supplied with a potential (e.g., an anode potential or a cathode potential) that is to be supplied to the common electrode 113. The connection electrode 111C is provided outside a display region where the pixels 150 are arranged.

The connection electrode 111C can be provided along the outer periphery of the display region. For example, the connection electrode 111C may be provided along one side of the outer periphery of the display region or two or more sides of the outer periphery of the display region. That is, in the case where the display region has a rectangular top surface shape, a top surface shape of the connection electrode 111C can have a belt-like shape, an L shape, a U shape (a square bracket shape), a quadrangular shape, or the like.

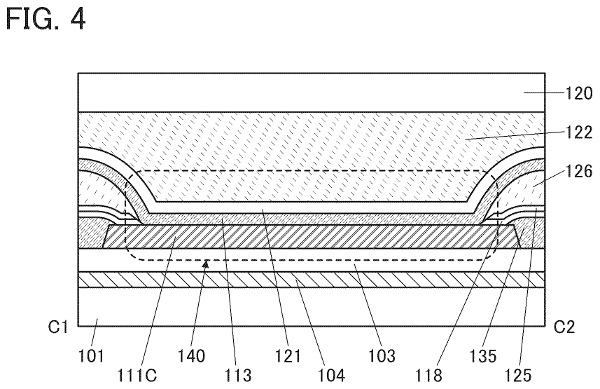

FIG. 4 is a schematic cross-sectional view taken along a dashed-dotted line C1-C2 in FIG. 1A. FIG. 4 illustrates a connection portion 140 where the connection electrode 111C and the common electrode 113 are electrically connected to each other. In the connection portion 140, the common electrode 113 is provided on and in contact with the connection electrode 111C and the protective layer 121 is provided to cover the common electrode 113. In addition, the insulating layer 135 is provided to cover end portions of the connection electrode 111C.

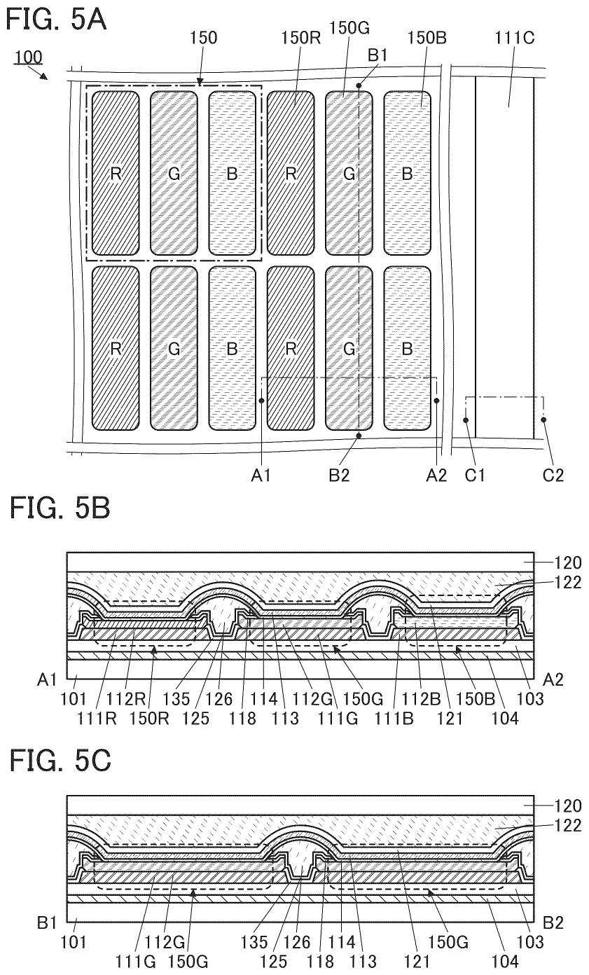

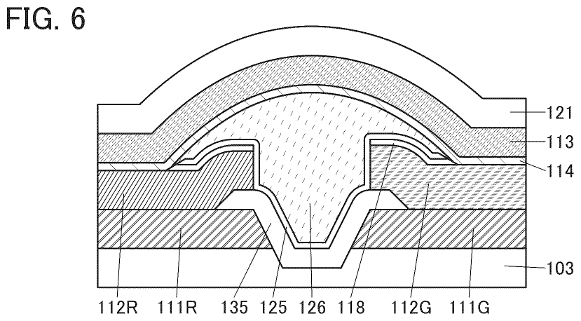

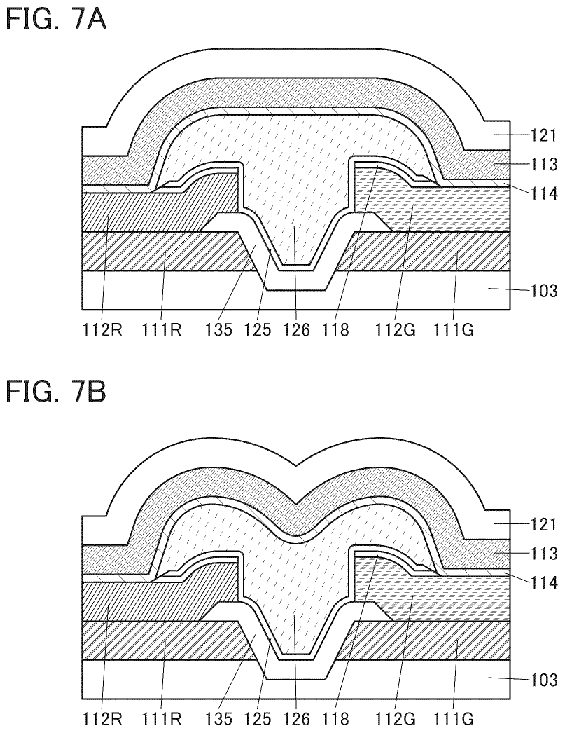

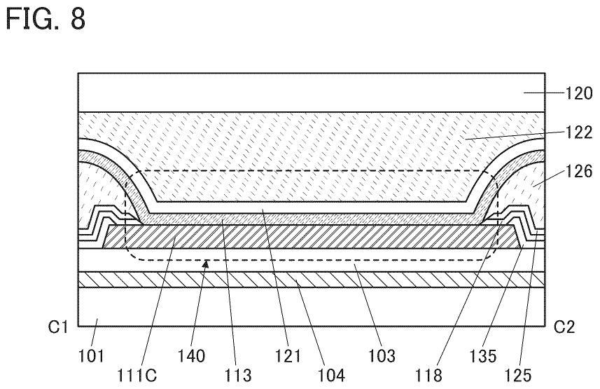

Although the structure in which the organic resin is used for the insulating layer 135 is described above, the inorganic insulating material can also be used for the insulating layer 135. FIG. 5A to FIG. 5C, FIG. 6, FIG. 7A, FIG. 7B, and FIG. 8 each illustrate an example in which the inorganic insulating material is used for the insulating layer 135. FIG. 6 and the like illustrate an example in which the portion of the insulating layer 103 that does not overlap with the pixel electrode 111R or the like is thinned.

With the use of an inorganic insulating material for the insulating layer 135, fine processing by a photolithography method can be performed accurately, whereby the distance between the adjacent pixels can be extremely smaller than that in the case of using an organic insulating material and thus the aperture ratio can be extremely high.

The end portion of the insulating layer 135 preferably has a tapered shape. Thus, step coverage with a film formed over the insulating layer 135, such as an EL layer provided to cover the end portion of the insulating layer 135, can be improved. The thickness of the insulating layer 135 is preferably smaller than that of the pixel electrode 111R or the like. When the insulating layer 135 is formed to be thin, step coverage with a film formed over the insulating layer 135 can be improved.

Examples of inorganic insulating material that can be used for the insulating layer 135 include oxides or nitrides such as silicon oxide, silicon oxynitride, silicon nitride oxide, silicon nitride, aluminum oxide, aluminum oxynitride, and hafnium oxide. Yttrium oxide, zirconium oxide, gallium oxide, tantalum oxide, magnesium oxide, lanthanum oxide, cerium oxide, neodymium oxide, or the like may be used.

In the insulating layer 135, films containing the above inorganic insulating materials may be stacked.

### MODIFICATION EXAMPLES

Modification examples of a display device will be described below.

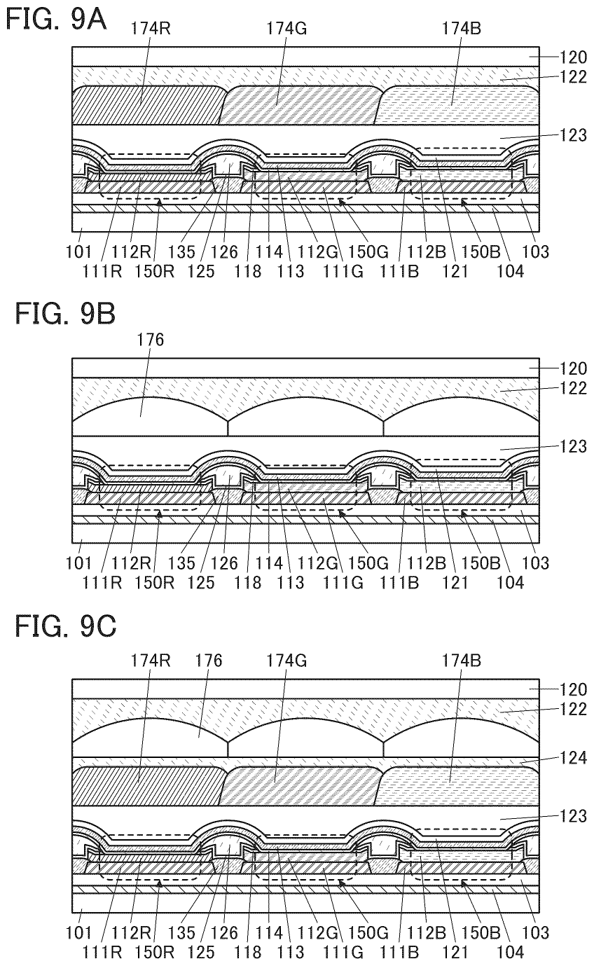

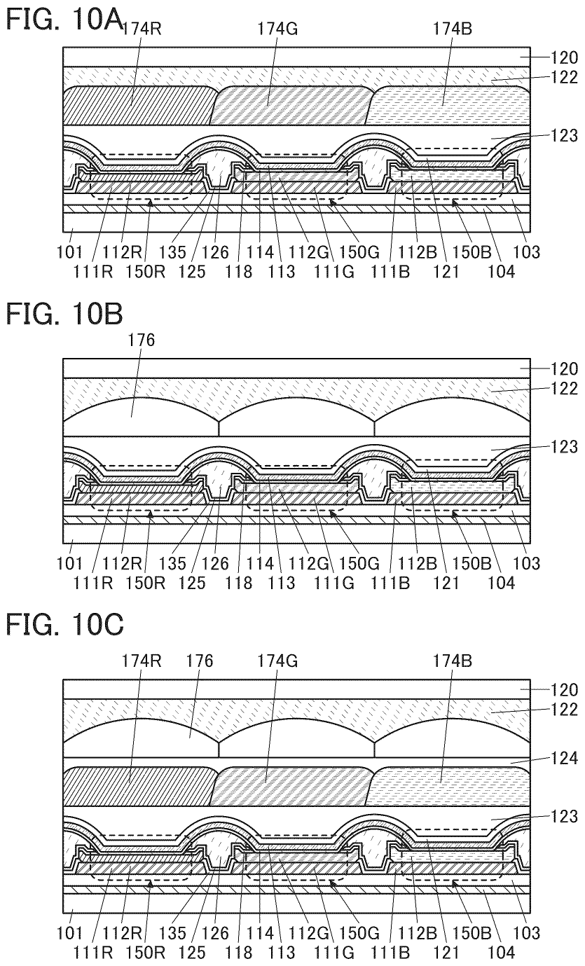

FIG. 9A to FIG. 9C illustrate examples in which the organic resin is used for the insulating layer 135, and FIG. 10A to FIG. 10C illustrate examples in which the inorganic insulating material is used for the insulating layer 135.

FIG. 9A and FIG. 10A each illustrate an example of the case where a coloring layer functioning as a color filter is used. The use of the coloring layer can increase color purity of light emitted from the display device. A planarization layer 123 is provided over the protective layer 121, and a coloring layer 174R, a coloring layer 174G, and a coloring layer 174B are provided over the planarization layer 123. The coloring layer 174R has a function of transmitting red light and absorbing light of the other color, and is provided in a position overlapping with the light-emitting element 150R. The coloring layer 174G has a function of transmitting green light and absorbing light of the other color, and is provided in a position overlapping with the light-emitting element 150G. The coloring layer 174B has a function of transmitting blue light and absorbing light of the other color, and is provided in a position overlapping with the light-emitting element 150B.

FIG. 9B and FIG. 10B each illustrate an example of the case where a lens array 176 is used. The lens array 176 is provided over the planarization layer 123. A plurality of lenses included in the lens array 176 are provided to overlap with any one of the light-emitting element 150R, the light-emitting element 150G, and the light-emitting element 150B. Accordingly, light extraction efficiency is improved, so that a brighter image can be displayed.

FIG. 9C and FIG. 10C each illustrate an example in which both the coloring layers and the lens array 176 are used. The coloring layer 174R, the coloring layer 174G, and the coloring layer 174B are provided over the planarization layer 123, a planarization layer 124 is provided to cover the coloring layer 174R, the coloring layer 174G, and the coloring layer 174B, and the lens array 176 is provided over the planarization layer 124.

Note that although the coloring layers and the lens are provided on the substrate 101 side in the above, they may be provided on the substrate 120 side.

The above is the description of the modification examples.

With the above-described display device, crosstalk due to leakage current is inhibited, so that an image with extremely high display quality can be displayed. Moreover, both a high aperture ratio and high resolution can be achieved. Thus, the display device can be suitably used for an extremely small display for a head-mounted display (a microdisplay). Note that without limited to this, one embodiment of the present invention can be used for an extremely small display that is less than one inch in size to an ultra-large display that is more than 100 inches in size.

### [Manufacturing Method Example]

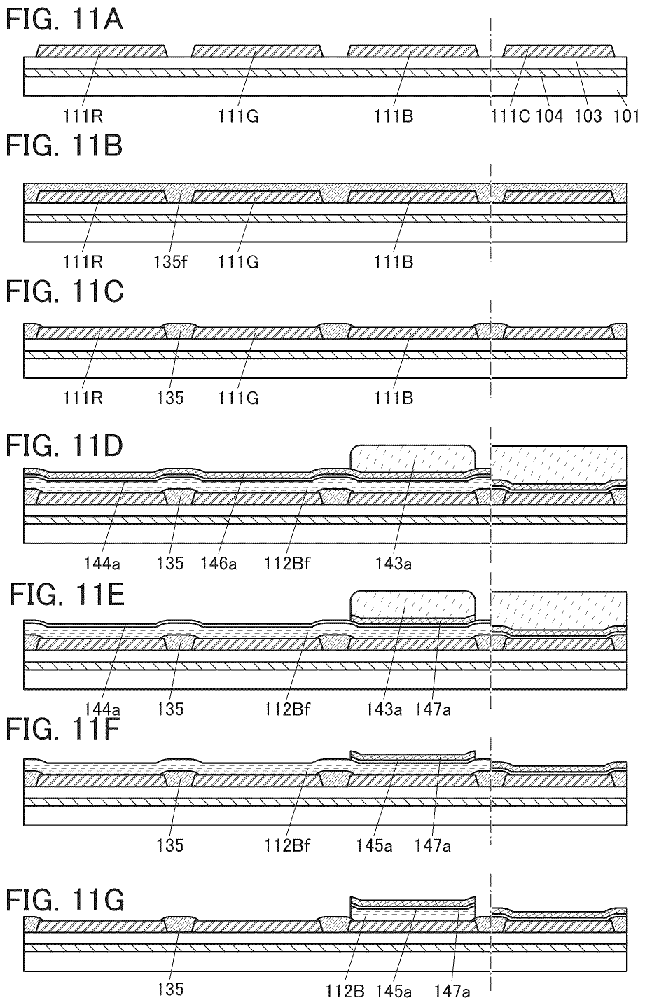

An example of a manufacturing method of the display device of one embodiment of the present invention will be described below with reference to drawings. Here, description is made using the display device 100 described in the above structure example as an example. FIG. 11A to FIG. 13F are each a cross-sectional schematic view of a step in a manufacturing method of the display device described below. In FIG. 11A and the like, the schematic cross-sectional view of the connection portion 140 and the vicinity thereof is also illustrated on the right side.

Note that thin films included in the display device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method and a thermal CVD method. An example of the thermal CVD method is a metal organic chemical vapor deposition (MOCVD: Metal Organic CVD) method.

Alternatively, thin films included in the display device (insulating films, semiconductor films, conductive films, or the like) can be formed by a method such as spin coating, dipping, spray coating, ink-jetting, dispensing, screen printing, offset printing, doctor blade coating, slit coating, roll coating, curtain coating, or knife coating.

The thin films included in the display device can be processed by a photolithography method or the like. Besides, a nanoimprinting method, a sandblasting method, a lift-off method, or the like may be used for the processing of the thin films. Alternatively, island-shaped thin films may be directly formed by a deposition method using a shielding mask such as a metal mask.

There are the following two typical methods of a photolithography method. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

For light used for light exposure in a photolithography method, for example, it is possible to use light with the i-line (wavelength: 365 nm), light with the g-line (wavelength: 436 nm), light with the h-line (wavelength: 405 nm), or combined light of any of them. Alternatively, ultraviolet light, KrF laser light, ArF laser light, or the like can be used. Light exposure may be performed by liquid immersion exposure technique. For light used for the light exposure, extreme ultraviolet (EUV) light, X-rays, or the like may be used. Furthermore, instead of light used for the light exposure, an electron beam can also be used. It is preferable to use extreme ultraviolet light, X-rays, or an electron beam because extremely minute processing can be performed. Note that a photomask is not needed when light exposure is performed by scanning with a beam such as an electron beam.

For etching of the thin film, a dry etching method, a wet etching method, a sandblast method, or the like can be used.

### [Preparation for Substrate 101]

For the substrate 101, a substrate having at least heat resistance high enough to withstand the following heat treatment can be used. In the case where an insulating substrate is used for the substrate 101, a glass substrate, a quartz substrate, a sapphire substrate, a ceramic substrate, an organic resin substrate, or the like can be used. Alternatively, a single crystal semiconductor substrate or a polycrystalline semiconductor substrate using silicon or silicon carbide as a material, a compound semiconductor substrate of silicon germanium or the like, or a semiconductor substrate such as an SOI substrate can be used.

### [Formation of Functional Layer 104 and Insulating Layer 103]

Next, the functional layer 104 and the insulating layer 103 are formed over the substrate 101. As the functional layer 104, a variety of circuits such as a pixel circuit can be formed by manufacturing a variety of functional elements such as a transistor, a wiring, and a capacitor with the use of known semiconductor process techniques.

As the insulating layer 103, an organic insulating film, an inorganic insulating film, or a stack of these films can be used. The organic insulating film is preferable because it can be used as a planarization film. After the inorganic insulating film is formed as the insulating layer 103, the top surface thereof may be planarized by planarization treatment.

In the case where an inorganic insulating film is used as the insulating layer 103, the insulating layer 103 is preferably deposited by a deposition method such as a sputtering method, a CVD method, or an ALD method. For example, as the insulating layer 103, it is possible to use an oxide film or a nitride film such as a silicon oxide film, a silicon oxynitride film, a silicon nitride oxide film, a silicon nitride film, an aluminum oxide film, an aluminum oxynitride film, or a hafnium oxide film.

In the case where an organic insulating film is used as the insulating layer 103, an organic insulating film of an acrylic resin, a polyimide resin, an epoxy resin, a polyamide resin, a polyimide-amide resin, a siloxane resin, a benzocyclobutene-based resin, a phenol resin, precursors of these resins, or the like can be used.

In the case where a stacked-layer film of an inorganic insulating film and an organic insulating film is used as the insulating layer 103, a structure in which an inorganic insulating film is stacked over an organic insulating film, a structure in which an organic insulating film is stacked over an inorganic insulating film, or the like can be employed.

In the case where an opening is provided in the insulating layer 103, the opening can be formed by forming a resist mask over the insulating layer 103 and partly etching the insulating layer 103. Alternatively, the insulating layer 103 including the opening may be formed using light exposure treatment and development treatment instead of etching treatment by using a photosensitive resin as the insulating layer 103. In the case where an organic insulating film is stacked over an inorganic insulating film, the opening can be formed in the insulating layer 103 by forming an organic insulating film including an opening and then removing an inorganic insulating film positioned in the opening of the organic insulating film by etching using the organic insulating film as a mask.

### [Formation of Pixel Electrodes 111R, 111G, and 111B and Connection Electrode 111C]

Next, a conductive film to be the pixel electrodes is formed over the insulating layer 103 and an unnecessary portion of the conductive film is removed by etching, so that the pixel electrode 111R, the pixel electrode 111G, the pixel electrode 111B, and the connection electrode 111C are formed (FIG. 11A).

At this time, a portion of the insulating layer 103 that is not covered with the pixel electrode 111 or the connection electrode 111C is etched and thinned in some cases.

In the case where a conductive film having a property of reflecting visible light is used as the pixel electrode 111, a material that has a reflectance as high as possible in the whole wavelength range of visible light (e.g., silver, aluminum, or the like) is preferably used. This can increase color reproducibility as well as light extraction efficiency of the light-emitting elements. A conductive film having a light-transmitting property may be stacked over a conductive film having a reflective property, and the thickness of the conductive film having a light-transmitting property may be different between the light-emitting elements and may be used as an optical adjustment layer. Alternatively, a structure may be employed in which an inorganic insulating layer having a light-transmitting property is formed over the pixel electrode 111 having a reflective property and a conductive layer having a light-transmitting property is formed over the inorganic insulating layer. In that case, the inorganic insulating layer is made different for each light-emitting element and can be used as an optical adjustment layer. Moreover, in that case, the pixel electrode 111 can be used for a reflective layer, and the conductive layer having a light-transmitting property over the inorganic insulating film can be used for the pixel electrode.

### [Formation of Insulating Layer 135]

Next, an insulating film 135f to be the insulating layer 135 later is formed to cover the insulating layer 103, the pixel electrodes 111, and the connection electrode 111C (FIG. 11B). It is particularly preferable to form the insulating film 135f by spin coating, ink-jetting, slit coating, or the like, in which case the thickness can be more uniform.

It is preferable to use a photosensitive organic resin for the insulating film 135f. After forming the insulating film 135f containing a photosensitive organic resin, light exposure treatment and development treatment are performed, whereby the insulating layer 135 covering the end portions of the pixel electrode 111 and end portions of the connection electrode 111C can be formed (FIG. 11C). Note that in the case where a non-photosensitive organic resin is used for the insulating film 135f, the insulating layer 135 may be formed by forming a resist mask thereover and processing the insulating film 135f by etching.

### [Formation of EL Film 112Bf]

Subsequently, an EL film 112Bf to be the EL layer 112B later is deposited over the pixel electrode 111R, the pixel electrode 111G, the pixel electrode 111B, and the insulating layer 135

The EL film 112Bf includes at least a film containing a light-emitting compound. Besides, a structure where one or more of films functioning as an electron-injection layer, an electron-transport layer, a charge-generation layer, a hole-transport layer, and a hole-injection layer are stacked may be employed. The EL film 112Bf can be formed by, for example, an evaporation method, a sputtering method, an inkjet method, or the like. Note that without limitation to this, the above film formation method can be used as appropriate.

In the case where the EL film 112Bf is deposited by an evaporation method (or a sputtering method), the EL film 112Bf can be deposited without using a high-resolution metal mask (FMM) for separately patterning an evaporated film for each pixel. The EL film 112Bf is preferably formed so as not to be provided over the connection electrode 111C. Therefore, the EL film 112Bf is preferably formed with the use of a shielding mask for shielding a region where an evaporated film is not to be formed such as a region of the connection electrode 111C.

[Formation of Sacrificial Film 144a]

Next, a sacrificial film 144a is formed to cover the EL film 112Bf. The sacrificial film 144a is provided to be in contact with a top surface of the connection electrode 111C.

As the sacrificial film 144a, it is possible to use a film highly resistant to etching treatment performed on the EL films such as the EL film 112Bf, i.e., a film that can have high etching selectivity. Furthermore, as the sacrificial film 144a, it is possible to use a film that can have high etching selectivity with respect to a protective film such as a sacrificial film 146a described later. Moreover, as the sacrificial film 144a, it is possible to use a film that can be removed by a wet etching method that is less likely to cause damage to the EL film.

As the sacrificial film 144a, for example, an inorganic film such as a metal film, an alloy film, a metal oxide film, a semiconductor film, or an inorganic insulating film can be suitably used. The sacrificial film 144a can be formed by any of a variety of film formation methods such as a sputtering method, an evaporation method, a CVD method, and an ALD method. In particular, an ALD method causes less damage to a layer where a film is formed; for this reason, the sacrificial film 144a, which is directly formed on the EL film 112Bf, is preferably formed by an ALD method.

Oxide such as aluminum oxide, hafnium oxide, or silicon oxide, nitride such as silicon nitride or aluminum nitride, or oxynitride such as silicon oxynitride can be used for the sacrificial film 144a. Although such an inorganic insulating material can be formed by a deposition method such as a sputtering method, a CVD method, an ALD method, or the like, an ALD method is particularly preferably used.

For the sacrificial film 144a, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver.

Alternatively, for the sacrificial film 144a, a metal oxide such as an indium gallium zinc oxide (In—Ga—Zn oxide, also referred to as IGZO) can be used. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon or the like can also be used.

Moreover, a material that can be dissolved in a solvent chemically stable with respect to at least the uppermost film of the EL film 112Bf is preferably used for the sacrificial film 144a. Specifically, a material that can be dissolved in water or alcohol can be suitably used for the sacrificial film 144a. In deposition of the sacrificial film 144a, it is preferable that application of such a material dissolved in a solvent such as water or alcohol be performed by a wet deposition process and then heat treatment for evaporating the solvent be performed. In that case, heat treatment is preferably performed in a reduced-pressure atmosphere, in which case the solvent can be removed at a low temperature in a short time, so that thermal damage to the EL film 112Bf can be reduced.

For the sacrificial film 144a, an organic material such as polyvinyl alcohol (PVA), polyvinylbutyral, polyvinylpyrrolidone, polyethylene glycol, polyglycerin, pullulan, a water-soluble cellulose, or an alcohol-soluble polyamide resin can be used.

Examples of the wet deposition processes that can be used for formation of the sacrificial film 144a include spin coating, dipping, spray coating, ink-jetting, dispensing, screen printing, offset printing, a doctor knife method, slit coating, roll coating, curtain coating, and knife coating.

[Formation of Sacrificial Film 146a]

Next, the sacrificial film 146a is formed over the sacrificial film 144a.

The sacrificial film 146a is a film used for a hard mask when the sacrificial film 144a is etched later. In a later step of processing the sacrificial film 146a, the sacrificial film 144a is exposed. Thus, a combination of films that can have high etching selectivity therebetween is selected for the sacrificial film 144a and the sacrificial film 146a. It is thus possible to select a film that can be used for the sacrificial film 146a depending on an etching condition of the sacrificial film 144a and an etching condition of the sacrificial film 146a.

A material of the sacrificial film 146a can be selected from a variety of materials depending on an etching condition of the sacrificial film 144a and an etching condition of the sacrificial film 146a. For example, any of the films that can be used for the sacrificial film 144a can be used.

Alternatively, as the sacrificial film 146a, an organic film that can be used as the EL film 112Bf or the like can be used. For example, the organic film that is used for an EL film 112Rf, an EL film 112Gf, or the EL film 112Bf can be used for the sacrificial film 146a. Such an organic film can be preferably used, in which case the film formation device for the EL film 112Bf or the like can be used in common.

When the sacrificial film 144a and the sacrificial film 146a contain different materials, high etching selectivity between the combination of the films can be easily achieved. For example, in the case where any of a metal film, an alloy film, an oxide film, a semiconductor film, an inorganic insulating film, and an organic film is used as the sacrificial film 144a, any of the other films is preferably used as the other film as the sacrificial film 146a.

As a more specific combination, for example, an oxide film such as an aluminum oxide film, a hafnium oxide film, a silicon oxide film, an indium gallium zinc oxide film, an indium zinc oxide film, or the like that is formed by an ALD method or a sputtering method can be used as the sacrificial film 144a, and a metal film or an alloy film containing tungsten, molybdenum, copper, titanium, aluminum, tantalum, or the like that is formed by a sputtering method or an evaporation method can be used as the sacrificial film 146a.

For example, an organic film (e.g., a PVA film) formed by an evaporation method or any of the above wet processes can be used as the sacrificial film 144a, and an inorganic film (e.g., a silicon oxide film or a silicon nitride film) formed by a sputtering method can be used as the sacrificial film 146a.

[Formation of Resist Mask 143a]

Then, over the sacrificial film 146a, the resist mask 143a is formed in each of a position overlapping with the pixel electrode 111B and part of the insulating layer 135 on the both sides of the pixel electrode 111B and a position overlapping with

[symbol]

### (FIG. 11D).

For the resist mask 143a, a resist material containing a photosensitive resin such as a positive type resist material or a negative type resist material can be used.

Here, in the case where the sacrificial film 146a is not provided and the resist mask 143a is formed over the sacrificial film 144a, if a defect such as a pinhole exists in the sacrificial film 144a, there is a risk of dissolving the EL film 112Bf due to a solvent of the resist material. Such a defect can be prevented by using the sacrificial film 146a.

Note that in the case where a film in which a defect such as a pinhole is unlikely to be generated is used as the sacrificial film 144a or a material that does not dissolve the EL film 112Bf is used for the solvent of the resist material, the resist mask 143a may be formed directly over the sacrificial film 144a without using the sacrificial film 146a in some cases.

[Etching of Sacrificial Film 146a]

Next, part of the sacrificial film 146a that is not covered by the resist mask 143a is removed by etching, so that an island-shaped sacrificial layer 147a is formed. At the same time, the sacrificial layer 147a is formed also over the connection electrode 111C (FIG. 11E).

In the etching of the sacrificial film 146a, an etching condition with high selectivity is preferably employed so that the sacrificial film 144a is not removed by the etching. Either wet etching or dry etching can be performed for the etching of the sacrificial film 146a; with use of dry etching, a reduction in a pattern of the sacrificial film 146a can be inhibited.

[Removal of Resist Mask 143a]

Then, the resist mask 143a is removed. The removal of the resist mask 143a can be performed by a wet etching method or a dry etching method. It is particularly preferable to perform dry etching (also referred to as plasma ashing) using an oxygen gas as an etching gas to remove the resist mask 143a.

In that case, the removal of the resist mask 143a is performed in a state where the EL film 112Bf is covered by the sacrificial film 144a; thus, the EL film 112Bf is less likely to be affected by the removal. This is particularly suitable in the case where etching using an oxygen gas, such as plasma ashing, is performed because the electrical characteristics might be adversely affected when the EL film 112Bf is exposed to oxygen.

[Etching of Sacrificial Film 144a]

Next, part of the sacrificial film 144a that is not covered with the sacrificial layer 147a is removed by etching using the sacrificial layer 147a as a mask, so that a sacrificial layer 145a is formed (FIG. 11F).

Either wet etching or dry etching can be performed for the etching of the sacrificial film 144a; however, a dry etching method is preferably used because a reduction in a pattern of the sacrificial film 144a can be inhibited.

### [Etching of EL Film 112Bf]

Next, part of the EL layer 112Bf is removed by etching using the sacrificial layer 147a as a mask, whereby the EL layer 112B is formed (FIG. 11G). The pixel electrode 111R and the pixel electrode 111G are exposed by the etching of the EL film 112Bf.

As the etching of the EL film 112Bf, anisotropic dry etching using an etching gas containing oxygen is preferably used because the etching rate can be increased. An etching gas that does not contain oxygen as its main component may be used.

Note that the etching gas is not limited thereto, and a hydrogen gas, a nitrogen gas, an oxygen gas, an ammonia gas, a chlorine gas, a noble gas, a gas containing fluorine such as CF₄, C₄F₈, SF₆, or CHF₃, or a gas containing chlorine such as BCl₃ can be used as the etching gas, for example. A mixed gas of two or more kinds of the above gases may also be used. Alternatively, a gas in which a noble gas such as argon, helium, xenon, or krypton is mixed in any of the above gases may be used as the etching gas.

Note that at the time of etching of the EL film 112Bf, the sacrificial layer 147a may also be removed. Accordingly, the manufacturing process can be simplified, so that the manufacturing costs of the display device can be reduced.

### [Formation of EL Film 112Gf]

Next, the EL film 112Gf to be the EL layer 112G is formed over the sacrificial layer 147a, the pixel electrode 111R, and the pixel electrode 111G.

The above description of the EL film 112Bf can be referred to for the formation method of the EL film 112Gf.

[Formation of Sacrificial Film 144b]

Subsequently, a sacrificial film 144b is formed over the EL film 112Gf. The sacrificial film 144b can be formed in a manner similar to that for the sacrificial film 144a. Specifically, the sacrificial film 144b is preferably formed using the same material as the sacrificial film 144a.

[Formation of Sacrificial Film 146b]

Next, a sacrificial film 146b is formed over the sacrificial film 144b. The sacrificial film 146b can be formed in a manner similar to that for the sacrificial film 146a. Specifically, the sacrificial film 146b is preferably formed using the same material as the sacrificial film 146a.

[Formation of Resist Mask 143b]

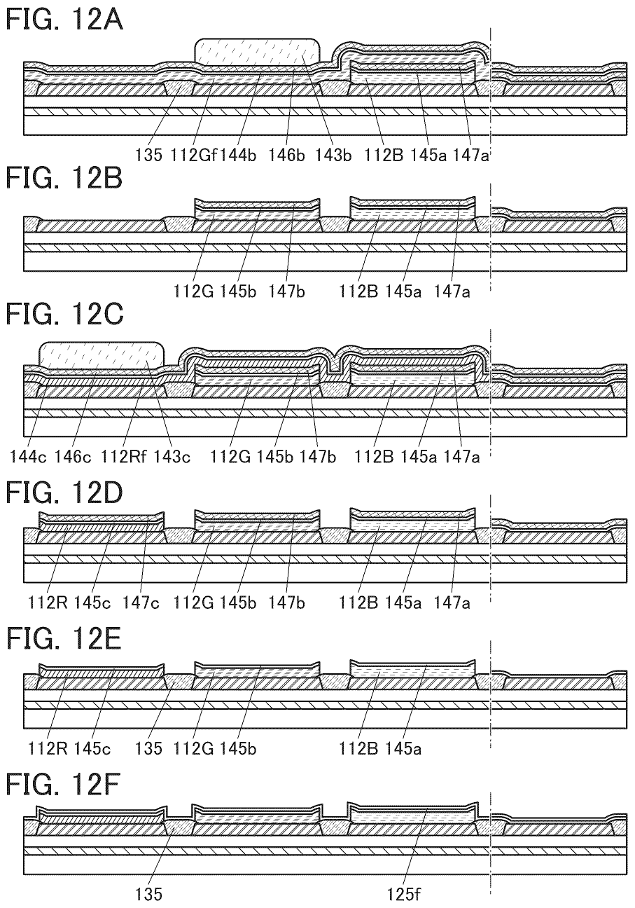

Next, a resist mask 143b is formed over the sacrificial film 146b (FIG. 12A). The resist mask 143b is formed in a region overlapping with the pixel electrode 111G.

The resist mask 143b can be formed in a manner similar to that for the resist mask 143a.

[Etching of Sacrificial Film 146b]

Next, part of the sacrificial film 146b that is not covered by the resist mask 143b is removed by etching, so that a island-shaped sacrificial layer 147b is formed.

The description of the sacrificial film 146a can be referred to for the etching of the sacrificial film 146b.

[Removal of Resist Mask 143b]

Next, the resist mask 143b is removed. The description of the resist mask 143a can be referred to for the removal of the resist mask 143b.

[Etching of Sacrificial Film 144b]

Next, part of the sacrificial film 144b that is not covered by the sacrificial layer 147b is removed by etching using the sacrificial layer 147b as a mask, so that an island-shaped sacrificial layer 145b is formed.

The description of the sacrificial film 144a can be referred to for the etching of the sacrificial film 144b.

### [Etching of EL Film 112Gf]

Next, part of the EL film 112Gf that is not covered with the sacrificial layer 145b is removed by etching, so that the island-shaped EL layer 112G is formed (FIG. 12B).

The description of the EL film 112Bf can be referred to for the etching of the EL film 112Gf.

In that case, since the EL layer 112B is protected by the sacrificial layer 145a and the sacrificial layer 147a, the EL layer 112B can be prevented from being damaged in the step of etching the EL film 112Gf.

In the above manner, the island-shaped EL layer 112B and the island-shaped EL layer 112G can be separately formed with high alignment accuracy.

### [Formation of EL Layer 112R]

The above steps are performed on the EL film 112Rf, whereby the EL layer 112R, a sacrificial layer 145c, and a sacrificial layer 147c which have an island shape can be formed over the pixel electrode 111R.

That is, after the EL layer 112G is formed, the EL film 112Rf, a sacrificial film 144c, a sacrificial film 146c, and a resist mask 143c are sequentially formed (FIG. 12C). Next, the sacrificial film 146c is etched to form the sacrificial layer 147c; then, the resist mask 143c is removed. Subsequently, the sacrificial film 144c is etched to form the sacrificial layer 145c. After that, the EL film 112Rf is etched to form the island-shaped EL layer 112R (FIG. 12D).

### [Removal of Sacrificial Layer 147]

Next, the sacrificial layer 147a, the sacrificial layer 147b, and the sacrificial layer 147c are removed to expose top surfaces of the sacrificial layer 145a, the sacrificial layer 145b, and the sacrificial layer 145c (FIG. 12E). In that case, the sacrificial layer 145a, the sacrificial layer 145b, and the sacrificial layer 145c are preferably left without being removed. Note that a method in which the sacrificial layer 147a, the sacrificial layer 147b, and the sacrificial layer 147c are not removed at this time but are etched in a later etching step of the sacrificial layer 145a, the sacrificial layer 145b, and the sacrificial layer 145c may be employed.

[Formation of Insulating Film 125f]

Next, an insulating film 125f is formed to cover the sacrificial layer 145a, the sacrificial layer 145b, the sacrificial layer 145c, and the insulating layer 135 (FIG. 12F).

The insulating film 125f is a layer to be the insulating layer 125 later. The thickness of the insulating film 125f is preferably larger than or equal to 3 nm, larger than or equal to 5 nm, or larger than or equal to 10 nm and smaller than or equal to 200 nm, smaller than or equal to 150 nm, smaller than or equal to 100 nm, or smaller than or equal to 50 nm.

The insulating film 125f, which is formed in contact with the side surface of the EL layer, is preferably formed by a formation method that causes less damage to the EL layer. In addition, the insulating film 125f is formed at a temperature lower than the heat-resistance temperature of the EL layer. The typical substrate temperatures in formation of the insulating film 125f and formation of the resin layer 126 performed later are each lower than or equal to 200° C., preferably lower than or equal to 180° C., further preferably lower than or equal to 160° C., still further preferably lower than or equal to 140° C., yet still further preferably lower than or equal to 120° C., yet still further preferably lower than or equal to 100° C.

For the insulating film 125f, a material different from that for the sacrificial film 146a is preferably used, and the same material as that for the sacrificial film 144a is further preferably used. For example, an aluminum oxide film is preferably formed by an ALD method. An ALD method is preferably used, in which case film formation damage can be reduced and a film with good coverage can be formed.

### [Formation of Resin Layer 126]

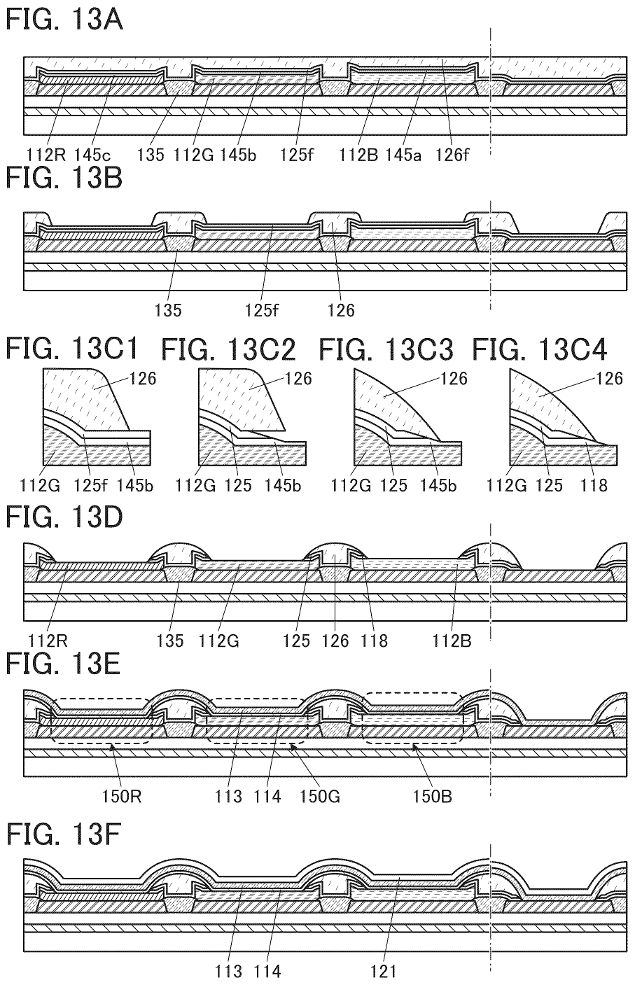

Next, a resin film 126f is formed over the insulating film 125f (FIG. 13A).

The resin film 126f is preferably formed by the aforementioned wet film formation method. For example, the resin film 126f is preferably formed by a film formation method such as spin coating, slit coating, and the like using a photosensitive resin, specifically, a photosensitive resin composite containing an acrylic resin.

After the resin film 126f is formed, heat treatment (also referred to as prebaking) is preferably performed. Heat treatment is performed at a temperature lower than the heat-resistance temperature of the EL layer 112R, the EL layer 112G, and the EL layer 112B. The substrate temperature in heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the resin film 126f can be removed.

Next, part of the resin film 126f is irradiated with visible rays or ultraviolet rays through a photomask, so that part of the resin film 126f is exposed to light. Here, in the case where a positive photosensitive resin is used for the resin film 126f, a portion where the resin film 126f is removed is irradiated with light. The resin layer 126 can be provided in regions sandwiched between any two of the pixel electrode 111R, the pixel electrode 111G, and the pixel electrode 111B and around the connection electrode 111C. Thus, the region inside the outline of each of the pixel electrode 111R, the pixel electrode 111G, and the pixel electrode 111B is irradiated with light.

Note that the shape of the resin layer 126 to be formed can be controlled by light irradiation range and light intensity. The resin layer 126 preferably covers part of the top surface in a vicinity of an end portion of the EL layer 112 and the width of a region where the EL layer 112 and the resin layer 126 overlap with each other is preferably as small as possible, in which case the light-emitting area can be increased.

Light used for light exposure preferably includes the i-line (wavelength: 365 nm). Furthermore, light used for the exposure may include at least one of the g-line (wavelength: 436 nm) and the h-line (wavelength: 405 nm).

Note that in the case where a negative photosensitive resin is used for the resin film 126f, a portion that is desired to be left is irradiated with light.

Next, development treatment is performed to remove part of the resin film 126f, whereby the resin layer 126 is formed (FIG. 13B). In the case where an acrylic resin is used for the resin film 126f, an alkaline solution is preferably used as a developer, and for example, an aqueous solution of tetramethyl ammonium hydroxide (TMAH) can be used.

Note that a step of removing a development residue (what is called a scum) may be performed after development. For example, the residue can be removed by ashing using oxygen plasma.

Etching treatment may be performed so that the height of the surface of the resin layer 126 is adjusted. For example, part of the resin layer 126 may be removed by ashing using oxygen plasma.

Note that after development and before post-baking, light exposure may be performed, in which the resin layer 126 is irradiated with visible rays or ultraviolet rays. In that case, light exposure may be performed without a photomask. Performing such light exposure after development can change the shape of the resin layer 126 into a tapered shape at low temperatures in some cases. Note that the light exposure is not necessarily performed.

At this time, the resin layer 126 has a cross-sectional shape with a flat top surface.

### [Formation of Insulating Layer 125 and Insulating Layer 118]

Next, unnecessary portions of the insulating film 125f, the sacrificial layer 145a, the sacrificial layer 145b, and the sacrificial layer 145c (hereinafter, also collectively referred to as a sacrificial layer 145) are removed by etching using the resin layer 126 as a mask, whereby the insulating layer 125 and the insulating layer 118 are formed.

The insulating film 125f and the sacrificial layer 145 may be etched at the same time in the same etching step. The insulating film 125f and the sacrificial layer 145 may be etched in a plurality of etching steps. An example in which the insulating film 125f and the sacrificial layer 145 are etched through two etching steps is described below.

FIG. 13C1 to FIG. 13C4 are enlarged views of the end portions of the resin layer 126 over the EL layer 112G and the vicinity thereof in each step. FIG. 13C1 corresponds to an enlarged view in the step illustrated in FIG. 13B.

First, in a first etching treatment using the resin layer 126 as a mask, an unnecessary portion of the insulating film 125f is removed and part of the sacrificial layer 145 is etched (FIG. 13C2). The insulating film 125f is etched to be the insulating layer 125.

At this time, it is preferable that the sacrificial layer 145 be processed to be thin but not removed so that the top surface of the EL layer 112G or the like is not exposed by removal of the sacrificial layer 145. For example, the thickness of the sacrificial layer 145 after the first etching treatment is less than or equal to 70%, preferably less than or equal to 60%, further preferably less than or equal to 50%, and greater than or equal to 5%, preferably greater than or equal to 10% of the thickness before the step. The thickness of the sacrificial layer 145 after the first etching treatment is preferably smaller, in which case the process time can be shortened even under a condition with a low etching rate in a second etching treatment. Note that the insulating film 125f may be etched by the first etching treatment and the sacrificial layer 145 may be etched by the second etching treatment.

A dry etching method or a wet etching method can be used for the first etching treatment.

In the case of performing dry etching, a gas containing chlorine (also referred to as a chlorine-based gas) is preferably used. As the chlorine-based gas, any of Cl2, BC13, SiCl4, CC14, and the like can be used alone or two or more of the gases can be mixed and used. Moreover, an oxygen gas, a hydrogen gas, a helium gas, an argon gas, or the like or a mixture of two or more of the gases can be added to the chlorine-based gas as appropriate. With the use of dry etching, the thickness of the sacrificial layer 145 after the etching can be controlled accurately and uniformity can be increased.

Wet etching is preferable because etching damage can be reduced as compared with dry etching. For example, the wet etching can be performed using an alkaline solution or the like. For example, for wet etching of an aluminum oxide film, it is preferable to use an aqueous solution of tetramethyl ammonium hydroxide (TMAH) that is an alkaline solution. In that case, puddle wet etching can be performed. Alternatively, wet etching using diluted hydrofluoric acid, oxalic acid, phosphoric acid, acetic acid, nitric acid, or a mixed solution thereof can be used. Alternatively, a mixed acid chemical solution containing water, phosphoric acid, diluted hydrofluoric acid, and nitric acid may be used. A chemical solution used for the wet etching treatment may be alkaline or acid.

Next, heat treatment (post-baking) is performed, whereby the resin layer 126 can be changed in shape. For example, the resin layer 126 having a flat top surface is preferably changed in its shape to have an arc-like cross-sectional shape. By the change in shape, as illustrated in FIG. 13C3, the end portion of the resin layer 126 is in contact with an end surface of the insulating layer 125 (e.g., including an inclined surface of the insulating layer 125) and a top surface of the sacrificial layer 145 (including an inclined surface of the sacrificial layer 145) in some cases.

For example, when post-baking is performed in a state where the EL layer 112 is not covered with the sacrificial layer 145 and exposed, the EL layer 112 is damaged and its characteristics deteriorate in some cases. In particular, when heat treatment is performed in a state where the EL layer 112 is exposed in an oxygen-containing atmosphere, deterioration might be further promoted. Therefore, the sacrificial layer 145 is left over the EL layer 122 after the first etching treatment, whereby deterioration due to post-baking can be inhibited.

Note that depending on a material and a formation method of the resin layer 126, the resin layer 126 may be changed in shape even in treatment other than post-baking, e.g., the first etching treatment or the second etching treatment described later.

Next, in the second etching treatment using the resin layer 126 as a mask, a remaining portion of the sacrificial layer 145 that is not covered with the resin layer 126 is removed to expose the top surface of the EL layer 112 (FIG. 13C4 and FIG. 13D). The sacrificial layer 145 is etched to be the insulating layer 118.

The second etching treatment is preferably performed by wet etching. Employing wet etching can reduce damage to the EL layer 112 as compared with the case of employing dry etching.

FIG. 13C4 illustrates an example in which part of a slope of the insulating layer 118 formed by the first etching treatment is covered with the resin layer 126 and part of a slope of the insulating layer 118 formed by the second etching treatment is not covered with the resin layer 126.

By using a method in which the etching treatment is divided into two steps and post-baking is performed between the steps, a gap can be prevented from being generated between the insulating layer 125 and the resin layer 126 and between the insulating layer 118 and the resin layer 126, so that a poor coverage of the common layer 114, the common electrode 113, or the like formed later can be less likely to occur.

Heat treatment may be performed after the second etching treatment. By heat treatment, moisture adsorbed onto a surface of the EL layer 112 or the like can be removed. The surface of the EL layer 112 can be prevented from being changed in quality due to being heated in a state of being exposed to oxygen by performing heat treatment in an inert gas atmosphere or a reduced-pressure atmosphere.

### [Formation of Common Layer 114 and Common Electrode 113]

Next, the common layer 114 is formed to cover the EL layer 112, the insulating layer 118, the insulating layer 125, and the resin layer 126. The common layer 114 can be formed by a sputtering method or a vacuum evaporation method, for example.

Then, the common electrode 113 is formed to cover the common layer 114 (FIG. 13E). The common electrode 113 can be formed by either or both of a sputtering method and a vacuum evaporation method, for example.

For example, in the case where a conductive film having properties of reflecting and transmitting visible light is used for the common electrode, a stacked-layer structure of a metal or alloy film that is thin enough to have a light-transmitting property and a conductive film having a light-transmitting property is preferably used. Note that a semiconductor film having a light-transmitting property (an oxide semiconductor film) may be used instead of the conductive film having a light-transmitting property.

Each of the common layer 114 and the common electrode 113 is not necessarily formed over the entire surface of the substrate 101, and is preferably formed using a shielding mask (also referred to as a metal mask or a rough metal mask) for specifying a film formation area. It is preferable that the common layer 114 be formed in a region where the light-emitting elements are provided and the common electrode be formed in a predetermined region including a region where the light-emitting elements are provided and a region where an electrode electrically connected to the common electrode 113 is provided.

The common layer 114 is preferably not provided over the connection electrode 111C, in which case the connection electrode 111C and the common electrode 113 can be directly connected to each other and the electric resistance therebetween can be reduced. In the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned over the connection electrode 111C. Accordingly, the common electrode 113 and the common layer 114 can be formed using the same shielding mask, so that manufacturing cost can be reduced.

In the above manner, the light-emitting element 150R, the light-emitting element 150G, and the light-emitting element 150B can be separately formed.

### [Formation of Protective Layer 121]

Next, the protective layer 121 is formed over the common electrode 113 (FIG. 13F). An inorganic insulating film used as the protective layer 121 is preferably formed by a sputtering method, a PECVD method, or an ALD method. In particular, an ALD method is preferable because it provides excellent step coverage and is less likely to cause a defect such as a pinhole.

### [Bonding of Substrate 120]

Lastly, the substrate 120 is bonded to each other with the adhesive layer 122 interposed therebetween.

In the case where the substrate 120 is a substrate on the viewer side, a light-transmitting substrate can be used as the substrate 120. In contrast, in the case where the substrate 120 is a substrate on the opposite side to the viewer side, although there is no limitation on the light-transmitting property of the substrate 120, using a substrate including a conductive member such as a metal or an alloy is particularly preferable because the heat dissipation property of the display device 100 is increased.

Through the above steps, the display device 100 illustrated in FIG. 1A and the like can be manufactured.

Although an example in which an organic resin is used for the insulating layer 135 is described above, an example in which an inorganic insulating material is used for the insulating layer 135 is described below. Note that hereinafter, the above description can be referred to for portions similar to those described above, and the description is not repeated.

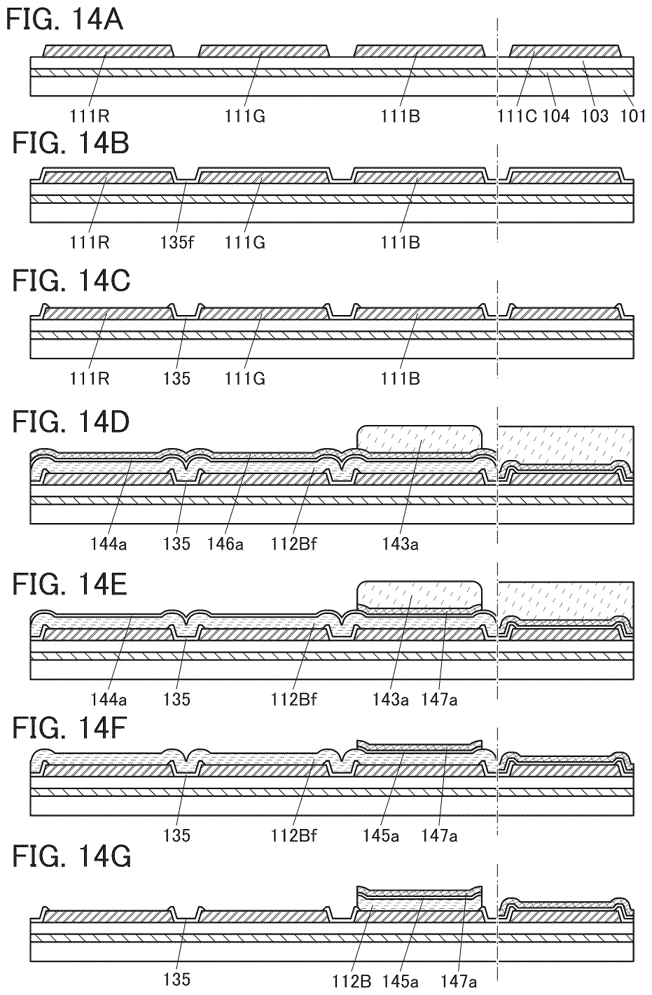

As described above, the functional layer 104, the insulating layer 103, the pixel electrode 111R, the pixel electrode 111G, the pixel electrode 111B, and the connection electrode 111C are formed over the substrate 101 (FIG. 14A).

The pixel electrode 111 and the connection electrode 111C are preferably processed so that their side surfaces have tapered shapes, in which case the step coverage with the insulating film 135f to be formed later is improved. In the case of using a dry etching method, for example, the tapered shapes can be obtained by performing etching under the condition where the resist mask and the conductive film can be etched at the same time. Note that the processing method for obtaining the tapered shapes is not limited thereto and the tapered shapes can also be obtained by wet etching in some cases.

Next, the insulating film 135f to be the insulating layer 135 later is formed to cover the insulating layer 103, the pixel electrodes 111, and the connection electrode 111C (FIG. 14B). The insulating film 135f is particularly preferably formed by a formation method such as a sputtering method, a plasma CVD method, or an ALD method, in which case a dense film can be formed at low temperatures.

After the formation of the insulating film 135f, an unnecessary portion is removed by etching, whereby the insulating layer 135 covering the end portion of the pixel electrode 111 and an end portion of the connection electrode 111C can be formed (FIG. 14C). At this time, the insulating film 135f is preferably processed so that the end portion of the insulating layer 135 have a tapered shape.

Note that the insulating layer 135 may be formed by a different method. For example, an insulating film to be the insulating layer 135 is formed over the insulating layer 103 and part of the insulating film is etched to form the insulating layer 135 having a lattice-shaped top surface. Next, a conductive film to be the pixel electrode 111 is formed to fill a depressed portion surrounded by the insulating layer 135, and planarization treatment is performed until the top surface of the insulating layer 135 is exposed, so that a pixel electrode embedded in the depressed portion is formed. The insulating layer 135 and the pixel electrode 111 (and the connection electrode 111C) can also be formed in such a manner. Note that heat treatment for reflow may be performed before planarization treatment.

As another method, after the pixel electrodes 111 and the connection electrode 111C are formed, the insulating film 135f to be the insulating layer 135 is formed thicker than the pixel electrode 111. After that, planarization treatment is performed until the top surface of the pixel electrode 111 is exposed, so that the insulating layer 135 that fills a depressed portion between the adjacent pixel electrodes 111 can be formed.

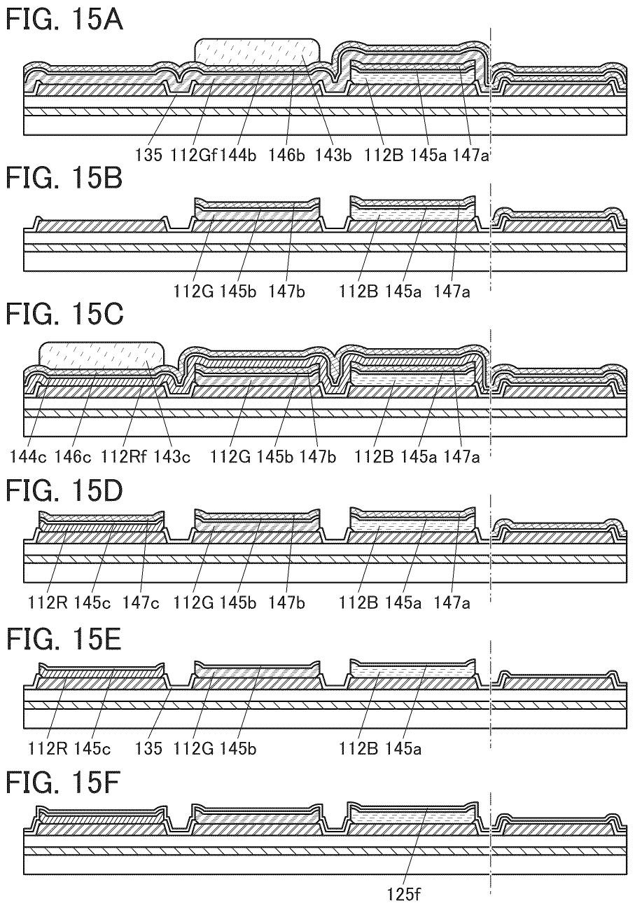

Next, the EL layer 112B, the sacrificial layer 145a, and the sacrificial layer 147a are formed by a method similar to the above (FIG. 14D to FIG. 14G). After that, the EL layer 112G, the sacrificial layer 145b, and the sacrificial layer 147b are formed (FIG. 15A and FIG. 15B) and then the EL layer 112R, the sacrificial layer 145c, and the sacrificial layer 147c are formed (FIG. 15C and FIG. 15D). After that, the sacrificial layer 147a, the sacrificial layer 147b, and the sacrificial layer 147c are removed (FIG. 15E).

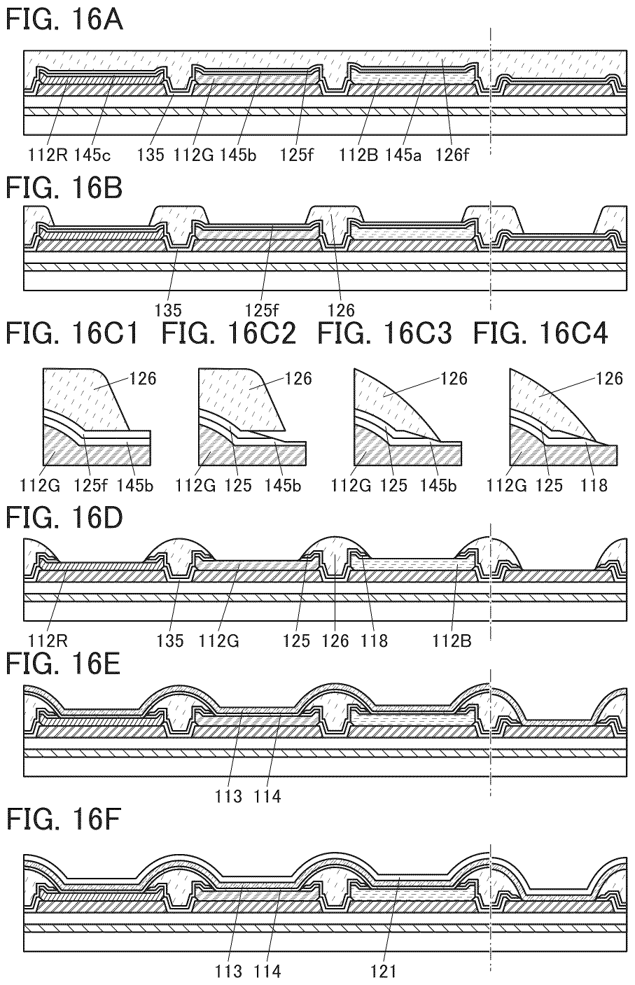

Next, the insulating layer 125, the insulating layer 126, and the insulating layer 118 are formed by a method similar to the above (FIG. 15F to FIG. 16D). After that, the common layer 114, the common electrode 113, and the protective layer 121 are formed (FIG. 16E and FIG. 16F), and the substrate 120 is bonded.

Through the above steps, the display device 100 illustrated in FIG. 5A and the like can be manufactured.

Although the EL layer 112B, the EL layer 112G, and the EL layer 112R are formed in this order in the above example, the formation order is not limited thereto.

Although the EL layer 112B has the largest thickness and the EL layer 112R has the smallest thickness in the above-described drawings of the EL layer 112, the thickness of each EL layer is not limited thereto. The difference in thickness between the EL layer 112R, the EL layer 112G, and the EL layer 112B is preferably set small, in which case the cross-sectional shape of the resin layer 126 can be close to bilaterally symmetrical, in which case the influence of the light-emitting element on the viewing angle characteristics can be reduced.

In the manufacturing method of a display device of one embodiment of the present invention, the island-shaped EL layer 112R, the island-shaped EL layer 112G, and the island-shaped EL layer 112B are not formed by using a fine metal mask but formed by processing a film formed with a uniform thickness; thus, excellent thickness uniformity in the pattern can be obtained. As a result, unevenness such as a difference in luminance depending on the place can be reduced, and the yield can be improved. Furthermore, the distance between the light-emitting elements can be reduced as compared with a method using a fine metal mask; thus, a display device with a high aperture ratio can be achieved. Furthermore, miniaturization of the size of the light-emitting element is possible, so that a display device with extremely high resolution can be achieved.

Furthermore, when an insulating layer covering the end portion of the pixel electrode and a resin layer covering the end portion of the EL layer are provided between adjacent light-emitting elements, leakage of a current between adjacent light-emitting elements can be prevented. This can inhibit unintended light emission due to the leakage current, so that a display device with high color reproducibility and high contrast can be provided.

At least part of this embodiment can be implemented in combination with the other embodiments described in this specification as appropriate.

### EMBODIMENT 2

In this embodiment, a display device of one embodiment of the present invention will be described.

### [Pixel Layout]

In this embodiment, pixel layouts different from the layout in FIG. 1A will be mainly described. There is no particular limitation on the arrangement of light-emitting elements (light-emitting devices) included in a pixel, and any of a variety of methods can be employed. The arrangement of light-emitting elements may be stripe arrangement, S stripe arrangement, matrix arrangement, delta arrangement, Bayer arrangement, or PenTile arrangement, for example.

A top surface shape of the light-emitting element illustrated in a drawing in this embodiment corresponds to a top surface shape of a light-emitting region (or a light-receiving region).

Examples of the top surface shape of the light-emitting element include polygons such as a triangle, a tetragon (including a rectangle and a square), and a pentagon; polygons with rounded corners; an ellipse; and a circle.

The range of the circuit layout of the pixels is not limited to the range of the light-emitting elements illustrated in the drawings and circuits may be placed outside the illustrated range of the light-emitting elements. In other words, the arrangement of the circuits and the arrangement of the light-emitting elements are not necessarily the same, and different arrangement methods may be employed. For example, the arrangement of the circuits may be stripe arrangement, and the arrangement of the light-emitting elements may be S-stripe arrangement.

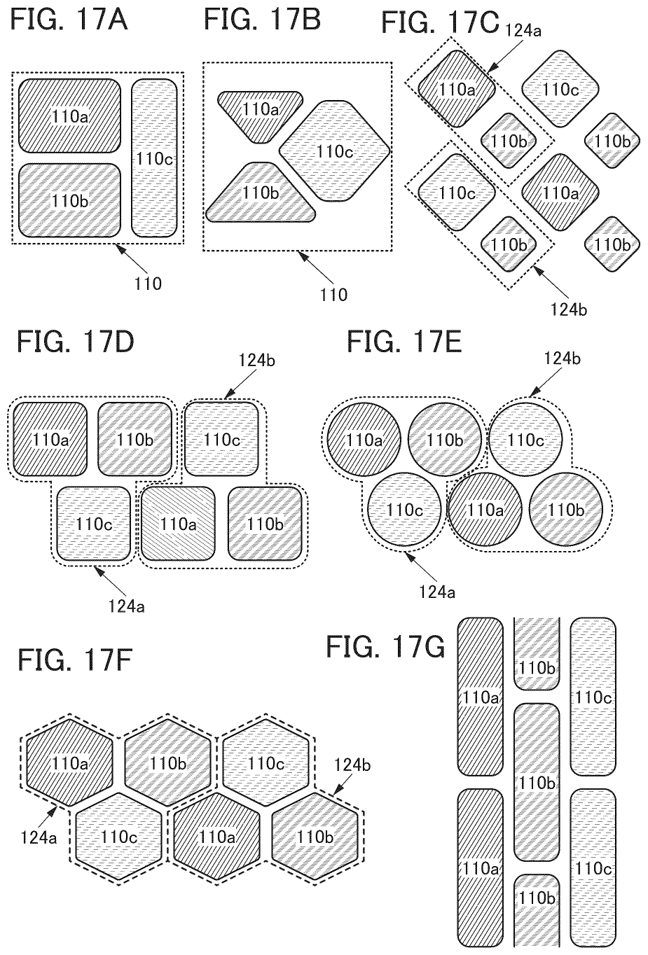

The pixel 110 illustrated in FIG. 17A employs S-stripe arrangement. The pixel 110 illustrated in FIG. 17A is composed of three light-emitting elements: light-emitting elements 110a, 110b, and 110c.

The pixel 110 illustrated in FIG. 17B includes a light-emitting element 110a whose top surface has a rough trapezoidal shape with rounded corners, a light-emitting element 110b whose top surface has a rough triangle shape with rounded corners, and a light-emitting element 110c whose top surface has a rough tetragonal or rough hexagonal shape with rounded corners. In addition, the light-emitting element 110a has a larger light-emitting area than the light-emitting element 110b. In this manner, the shapes and sizes of the light-emitting elements can be determined independently. For example, the size of a light-emitting element with higher reliability can be made smaller.

Pixels 124a and 124b illustrated in FIG. 17C employ a PenTile arrangement. FIG. 17C illustrates an example in which the pixels 124a each including the light-emitting element 110a and the light-emitting element 110b and the pixels 124b each including the light-emitting element 110b and the light-emitting element 110c are alternately arranged.

The pixels 124a and 124b illustrated in FIG. 17D to FIG. 17F employ delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row).

FIG. 17D illustrates an example in which each light-emitting element has a rough tetragonal top surface shape with rounded corners, FIG. 17E illustrates an example in which each light-emitting element has a circular top surface shape, and FIG. 17F illustrates an example in which each light-emitting element has a rough hexagonal top surface shape with rounded corners.

In FIG. 17F, light-emitting elements are placed inside the closest-packed hexagonal regions. Focusing on one of the light-emitting elements, the light-emitting element is placed to be surrounded by six light-emitting elements. The light-emitting elements are provided such that light-emitting elements that emit light of the same color are not adjacent to each other. For example, focusing on the light-emitting element 110a, the light-emitting element 110a is surrounded by three light-emitting elements 110b and three light-emitting elements 110c that are alternately placed.

FIG. 17G illustrates an example in which light-emitting elements of different colors are arranged in a zigzag manner. Specifically, the positions of top sides of two light-emitting elements arranged in a column direction (e.g., the light-emitting element 110a and the light-emitting element 110b or the light-emitting element 110b and the light-emitting element 110c) are not aligned in a top view.

In the pixels illustrated in FIG. 17A to FIG. 17G, for example, the light-emitting element 110a is preferably a light-emitting element (R) emitting red light, the light-emitting element 110b is preferably a light-emitting element (G) emitting green light, and the light-emitting element 110c is preferably a light-emitting element (B) emitting blue light. Note that the structure of the light-emitting elements is not limited to this, and the colors and arrangement order of the light-emitting elements can be determined as appropriate. For example, the light-emitting element 110b may be the light-emitting element (R) emitting red light and the light-emitting element 110a may be the light-emitting element (G) emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, a top surface of a light-emitting element has a polygonal shape with rounded corners, an elliptical shape, a circular shape, or the like in some cases.

Furthermore, in the manufacturing method of the display device of one embodiment of the present invention, the EL layer is processed into an island shape using a resist mask. A resist film formed over the EL layer needs to be cured at a temperature lower than the heat-resistance temperature of the EL layer. Therefore, the resist film is insufficiently cured in some cases depending on the heat-resistance temperature of the material of the EL layer and the curing temperature of the resist material. An insufficiently cured resist film may have a shape different from a desired shape at the time of processing. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

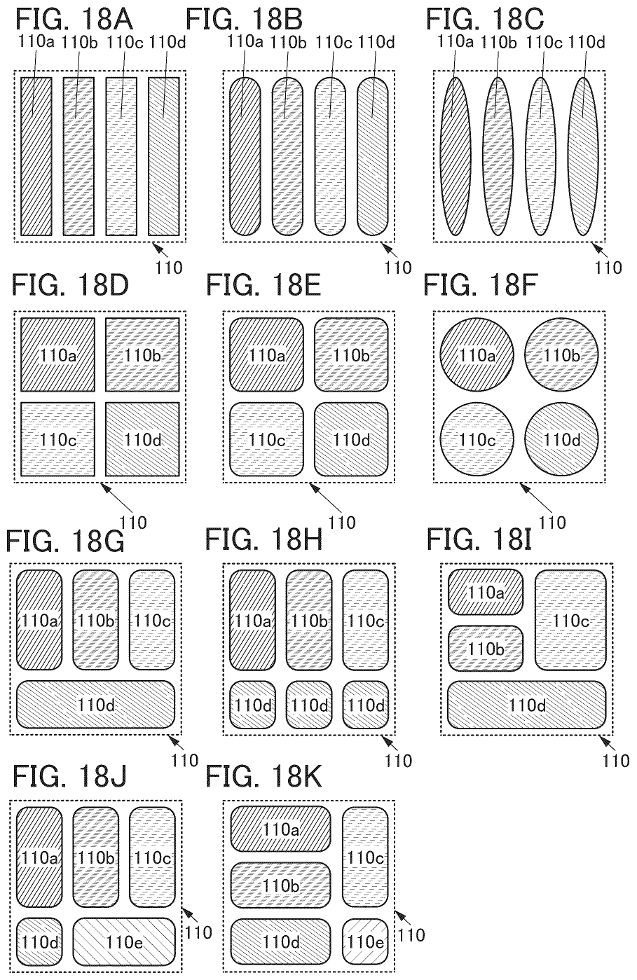

As illustrated in FIG. 18A to FIG. 18I, the pixel can include four kinds of light-emitting elements.

The pixels 110 illustrated in FIG. 18A to FIG. 18C employ stripe arrangement.

FIG. 18A illustrates an example in which each light-emitting element has a rectangular top surface shape, FIG. 18B illustrates an example in which each light-emitting element has a top surface shape formed by combining two half circles and a rectangle, and FIG. 18C illustrates an example in which each light-emitting element has an elliptical top surface shape.

The pixels 110 illustrated in FIG. 18D to FIG. 18F employ matrix arrangement.

FIG. 18D illustrates an example in which each light-emitting element has a square top surface shape, FIG. 18E illustrates an example in which each light-emitting element has a substantially square top surface shape with rounded corners, and FIG. 18F illustrates an example in which each light-emitting element has a circular top surface shape.

FIG. 18G and FIG. 18H each illustrate an example in which one pixel 110 is composed of two rows and three columns.

The pixel 110 illustrated in FIG. 18G includes three light-emitting elements (the light-emitting elements 110a, 110b, and 110c) in the upper row (first row) and one light-emitting element (a light-emitting element 110d) in the lower row (second row). In other words, the pixel 110 includes the light-emitting element 110a in the left column (first column), the light-emitting element 110b in the center column (second column), the light-emitting element 110c in the right column (third column), and the light-emitting element 110d across these three columns.

The pixel 110 illustrated in FIG. 18H includes three light-emitting elements (the light-emitting elements 110a, 110b, and 110c) in the upper row (first row) and three light-emitting elements 110d in the lower row (second row). In other words, the pixel 110 includes the light-emitting element 110a and the light-emitting element 110d in the left column (first column), the light-emitting element 110b and the light-emitting element 110d in the center column (second column), and the light-emitting element 110c and the light-emitting element 110d in the right column (third column). Aligning the positions of the light-emitting elements in the upper row and the lower row as illustrated in FIG. 18H enables efficient removal of dust and the like that would be produced in the manufacturing process. Thus, a display device with high display quality can be provided.

FIG. 18I illustrates an example in which one pixel 110 is composed of three rows and two columns.

The pixel 110 illustrated in FIG. 18I includes the light-emitting element 110a in the upper row (first row), the light-emitting element 110b in the center row (second row), the light-emitting element 110c across the first and second rows, and one light-emitting element (the light-emitting element 110d) in the lower row (third row). In other words, the pixel 110 includes the light-emitting elements 110a and 110b in the left column (first column), the light-emitting element 110c in the right column (second column), and the light-emitting element 110d across these two columns.

The pixels 110 illustrated in FIG. 18A to FIG. 18I are each composed of four light-emitting elements: the light-emitting elements 110a, 110b, 110c, and 110d.

The light-emitting elements 110a, 110b, 110c, and 110d can emit light of different colors. The light-emitting elements 110a, 110b, 110c, and 110d can be light-emitting elements of four colors of R, G, B, and white (W), light-emitting elements of four colors of R, G, B, and Y, or light-emitting elements of R, G, B, and infrared light (IR), for example.

In the pixels 110 illustrated in FIG. 18A to FIG. 18I, the light-emitting element 110a is preferably a light-emitting element (R) emitting red light, the light-emitting element 110b is preferably a light-emitting element (G) emitting green light, the light-emitting element 110c is preferably a light-emitting element (B) emitting blue light, and the light-emitting element 110d is preferably any of a light-emitting element (W) emitting white light, a light-emitting element (Y) emitting yellow light, and a light-emitting element (IR) emitting near-infrared light, for example. In the case where such a structure is employed, stripe arrangement is employed as the layout of R, G, and B in the pixels 110 illustrated in FIG. 18G and FIG. 18H, leading to higher display quality. In addition, what is called S-stripe arrangement is employed as the layout of R, G, and B in the pixel 110 illustrated in FIG. 18I, leading to higher display quality.

The pixel 110 may include a light-receiving element (light-receiving device).

In the pixels 110 illustrated in FIG. 18A to FIG. 18I, any one of the light-emitting element 110a to the light-emitting element 110d may be a light-receiving element.

In the pixels 110 illustrated in FIG. 18A to FIG. 18I, for example, it is preferable that the light-emitting element 110a be the light-emitting element (R) emitting red light, the light-emitting element 110b be the light-emitting element (G) emitting green light, the light-emitting element 110c be the light-emitting element (B) emitting blue light, and the light-emitting element 110d be the light-receiving element(S). In the case where such a structure is employed, stripe arrangement is employed as the layout of R, G, and B in the pixels 110 illustrated in FIG. 18G and FIG. 18H, leading to higher display quality. In addition, what is called S-stripe arrangement is employed as the layout of R, G, and B in the pixel 110 illustrated in FIG. 18I, leading to higher display quality.

There is no particular limitation on the wavelength of light detected by the light-receiving element. The light-receiving element can detect one or both of visible light and infrared light. As illustrated in FIG. 18J and FIG. 18K, the pixel can include five types of light-emitting elements.

FIG. 18J illustrates an example in which one pixel 110 is composed of two rows and three columns.

The pixel 110 illustrated in FIG. 18J includes three light-emitting elements (the light-emitting elements 110a, 110b, and 110c) in the upper row (first row) and two light-emitting elements (the light-emitting elements 110d and 110e) in the lower row (second row). In other words, the pixel 110 includes the light-emitting elements 110a and 110d in the left column (first column), the light-emitting element 110b in the center column (second column), the light-emitting element 110c in the right column (third column), and the light-emitting element 110e across the second and third columns.

FIG. 18K illustrates an example in which one pixel 110 is composed of three rows and two columns.

The pixel 110 illustrated in FIG. 18K includes the light-emitting element 110a in the upper row (first row), the light-emitting element 110b in the center row (second row), the light-emitting element 110c across the first and second rows, and two light-emitting elements (the light-emitting elements 110d and 110e) in the lower row (third row). In other words, the pixel 110 includes the light-emitting elements 110a, 110b, and 110d in the left column (first column), and the light-emitting elements 110c and 110e in the right column (second column).

In the pixels 110 illustrated in FIG. 18J and FIG. 18K, for example, it is preferable that the light-emitting element 110a be the light-emitting element (R) emitting red light, the light-emitting element 110b be the light-emitting element (G) emitting green light, and the light-emitting element 110c be the light-emitting element (B) emitting blue light. In the case where such a structure is employed, stripe arrangement is employed as the layout of R, G, and B in the pixel 110 illustrated in FIG. 18J, leading to higher display quality. In addition, what is called S-stripe arrangement is employed as the layout of R, G, and B in the pixel 110 illustrated in FIG. 18K, leading to higher display quality.

In the pixels 110 illustrated in FIG. 18J and FIG. 18K, the light-receiving element(S) may be used as one or both of the light-emitting element 110d and the light-emitting element 110e, for example. In the case where light-receiving elements are used in both the light-emitting element 110d and the light-emitting element 110e, the light-receiving elements may have different structures. For example, the wavelength ranges of detected light may be different at least partly. Specifically, one of the two light-receiving elements may mainly detect visible light and the other may mainly detect infrared light.

In the pixels 110 illustrated in FIG. 18J and FIG. 18K, for example, it is preferable that the light-receiving element S be used as either one of the light-emitting element 110d and the light-emitting element 110e and a light-emitting element that can be used as a light source be used as the other. For example, a light-emitting element IR emitting infrared light and a light-receiving element detecting infrared light are preferably included.

In a pixel including the light-emitting element R, the light-emitting element G, the light-emitting element B, the light-emitting element IR, and the light-receiving element S, while an image is displayed using the light-emitting element R, the light-emitting element G, and the light-emitting element B, reflected light of infrared light emitted from the light-emitting element IR can be detected by the light-receiving element S using the light-emitting element IR as a light source.

As described above, the pixel each including the light-emitting element can employ any of a variety of layouts in the display device of one embodiment of the present invention. The display device of one embodiment of the present invention can have a structure in which the pixel includes both a light-emitting element and a light-receiving element. Also in this case, any of a variety of layouts can be employed.

At least part of this embodiment can be implemented in combination with the other embodiments described in this specification as appropriate.

### EMBODIMENT 3

In this embodiment, the display device of one embodiment of the present invention will be described with reference to drawings.

The display device of this embodiment can be a high-resolution display device. For example, display devices of one embodiment of the present invention can be used for display portions of information terminal devices (wearable devices) such as wristwatch-type and bracelet-type information terminal devices and display portions of wearable devices that can be worn on a head, such as VR devices like head-mounted displays and glasses-type AR devices.

### [Display Module]

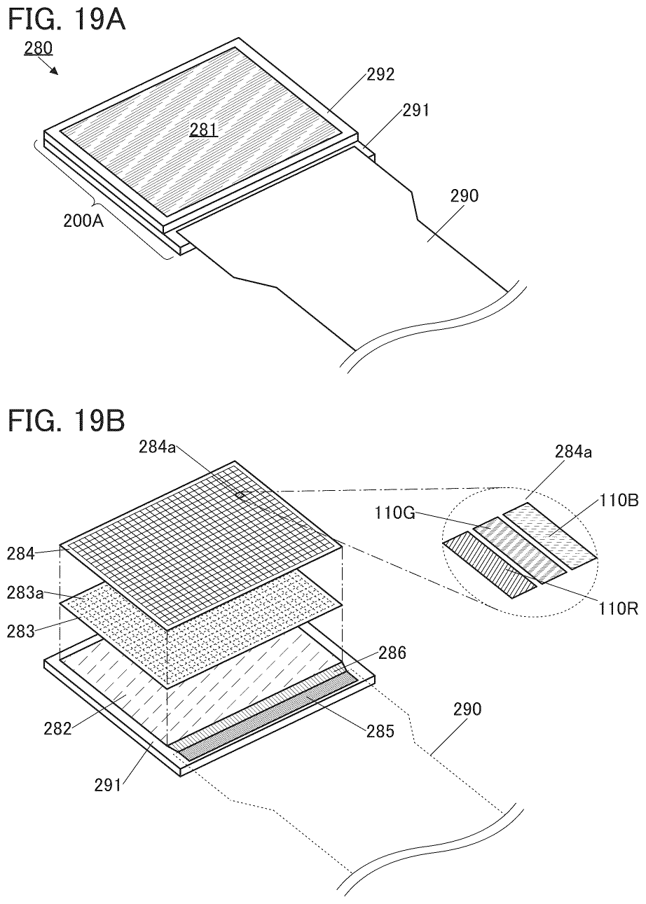

FIG. 19A is a perspective view of a display module 280. The display module 280 includes a display device 200A and an FPC 290. Note that a display panel included in the display module 280 is not limited to the display device 200A and may be any of a display device 200B to a display device 200F described later.

The display module 280 includes a substrate 291 and a substrate 292. The display module 280 includes a display portion 281. The display portion 281 is a region where an image is displayed.

FIG. 19B shows a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is shown on the right side of FIG. 19B. The pixel 284a includes a light-emitting element 110R that emits red light, a light-emitting element 110G that emits green light, and a light-emitting element 110B that emits blue light.

The pixel circuit portion 283 includes a plurality of pixel circuits 283a arranged periodically. One pixel circuit 283a is a circuit controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. An IC may be mounted on the FPC 290.

The display module 280 can have a structure where one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even with a structure where the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device, such as a wrist watch.

### [Display Device 200A]

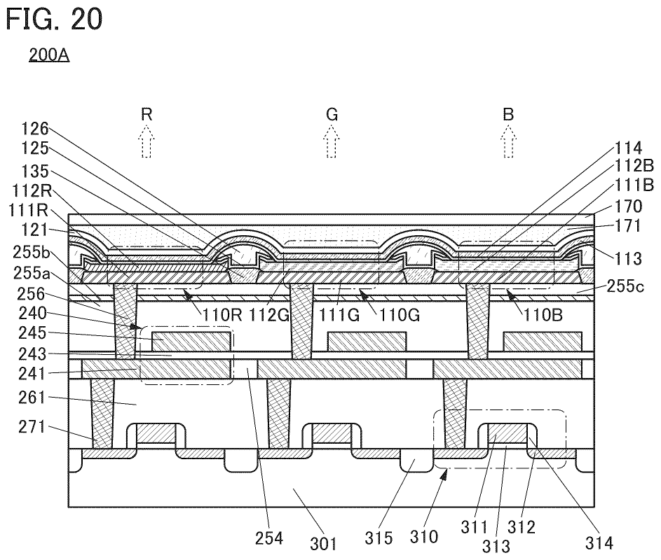

The display device 200A illustrated in FIG. 20 includes a substrate 301, the light-emitting elements 110R, 110G, and 110B, a capacitor 240, and a transistor 310.

The substrate 301 corresponds to the substrate 291 in FIG. 19A and FIG. 19B.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region of the substrate 301 which is doped with an impurity, and functions as one of a source and a drain. The insulating layers 314 are provided to cover side surfaces of the conductive layer 311.

In addition, an element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to function as an etching protective film. Although this embodiment shows an example in which the insulating layer 255c is partly etched and a depressed portion is formed, the depressed portion is not necessarily provided in the insulating layer 255c.

The light-emitting element 110R, the light-emitting element 110G, and the light-emitting element 110B are provided over the insulating layer 255c. Embodiment 1 can be referred to for the structures of the light-emitting element 110R, the light-emitting element 110G, and the light-emitting element 110B.

In the display device 200A, since the light-emitting devices of different colors are separately formed, a change in chromaticity between light emission at low luminance and light emission at high luminance is small. Furthermore, since the EL layers 112R, 112G, and 112B are separated from each other, crosstalk generated between adjacent subpixels can be inhibited even when the display panel has high resolution. Accordingly, the display panel can have high resolution and high display quality.

In a region between adjacent light-emitting elements, the insulating layer 135, an insulating layer 125, and a resin layer 126 are provided. The insulating layer 135 is provided to cover end portions of the pixel electrode 111R, the pixel electrode 111G, and the pixel electrode 111B. The insulating layer 125 and the resin layer 126 are provided over the insulating layer 135 and cover end portions of the EL layers.

The pixel electrode 111R, the pixel electrode 111G, and the pixel electrode 111B of the light-emitting elements are each electrically connected to one of the source and the drain of the transistor 310 through a plug 256 that is embedded in the insulating layer 255a, the insulating layer 255b, and the insulating layer 255c, the conductive layer 241 that is embedded in the insulating layer 254, and the plug 271 that is embedded in the insulating layer 261. The top surface of the insulating layer 255c and the top surface of the plug 256 are level or substantially level with each other. A variety of conductive materials can be used for the plugs.

In addition, the protective layer 121 is provided over the light-emitting elements 110R, 110G, and 110B. A substrate 170 is attached to the protective layer 121 with an adhesive layer 171.

### [Display Device 200B]

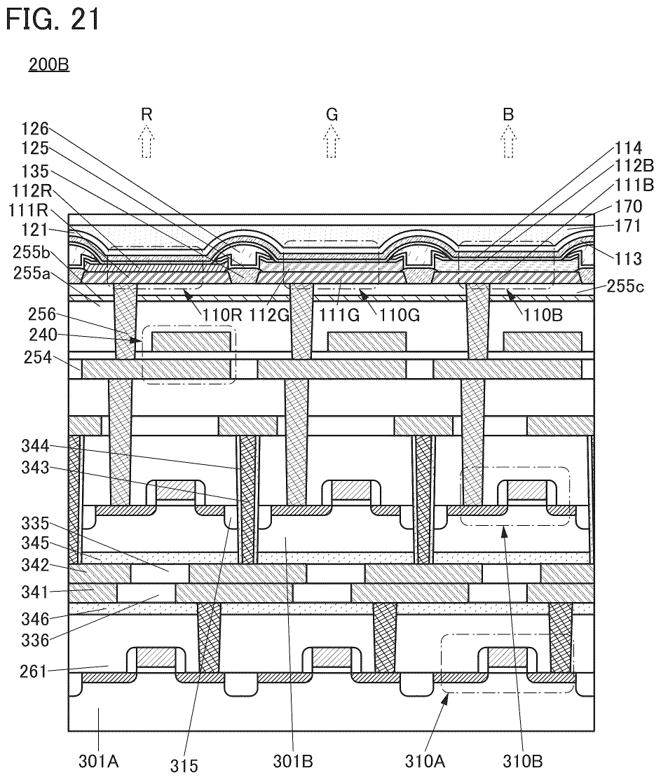

The display device 200B illustrated in FIG. 21 has a structure in which a transistor 310A and a transistor 310B in each of which a channel is formed in a semiconductor substrate are stacked. Note that in the following description of the display panel, the description of portions similar to those of the above display panel is omitted in some cases.

The display device 200B has a structure where a substrate 301B provided with the transistors 310B, the capacitors 240, and the light-emitting devices is attached to a substrate 301A provided with the transistors 310A.

Here, an insulating layer 345 is provided on the bottom surface of the substrate 301B, and an insulating layer 346 is provided over the insulating layer 261 provided over the substrate 301A. The insulating layers 345 and 346 are insulating layers functioning as protective layers and can inhibit diffusion of impurities into the substrate 301B and the substrate 301A. As the insulating layers 345 and 346, an inorganic insulating film that can be used as the protective layer 121 or an insulating layer 332 can be used.

The substrate 301B is provided with a plug 343 that penetrates the substrate 301B and the insulating layer 345. Here, an insulating layer 344 functioning as a protective layer is preferably provided to cover the side surface of the plug 343.

A conductive layer 342 is provided under the insulating layer 345 on the substrate 301B. The conductive layer 342 is embedded in an insulating layer 335, and the bottom surfaces of the conductive layer 342 and the insulating layer 335 are planarized. The conductive layer 342 is electrically connected to the plug 343.

A conductive layer 341 is provided over the insulating layer 346 over the substrate 301A. The conductive layer 341 is embedded in an insulating layer 336, and the top surfaces of the conductive layer 341 and the insulating layer 336 are planarized.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Device 200C]

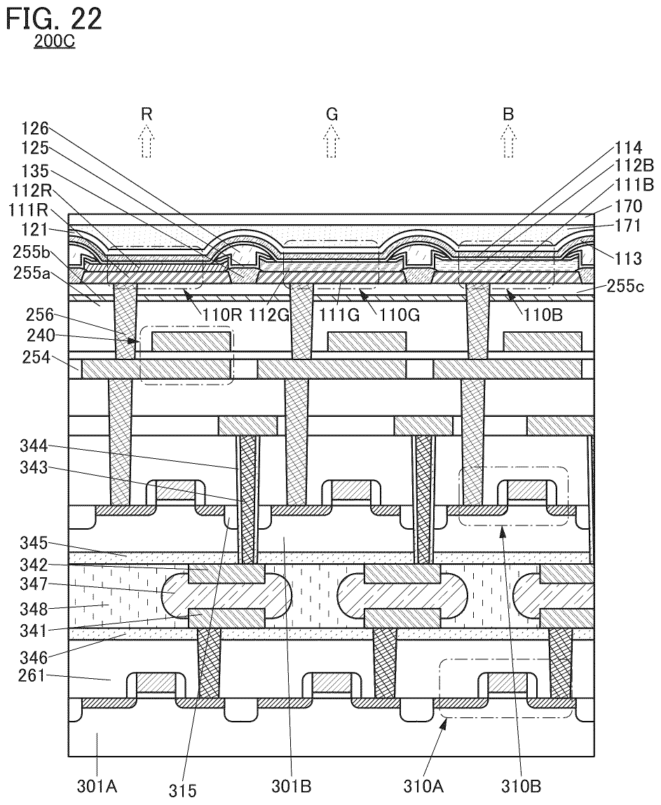

The display device 200C illustrated in FIG. 22 has a structure where the conductive layer 341 and the conductive layer 342 are bonded to each other through a bump 347.

As shown in FIG. 22, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 200D]

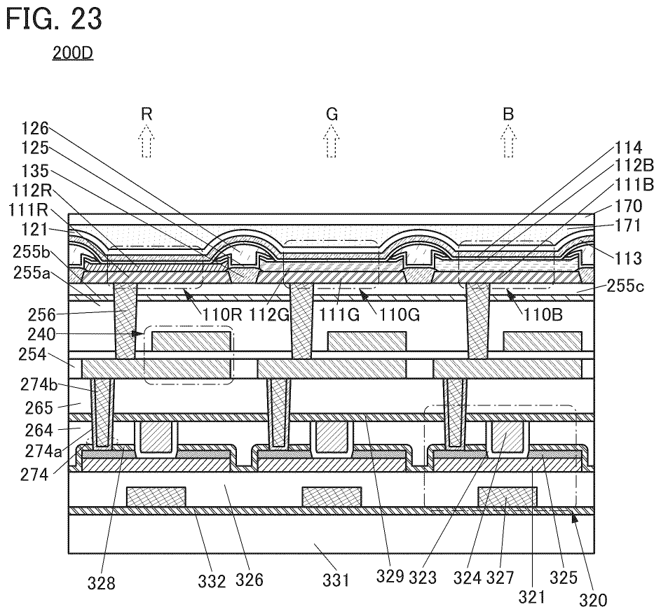

The display device 200D illustrated in FIG. 23 differs from the display device 200A mainly in a transistor structure.

A transistor 320 is a transistor (OS transistor) that includes a metal oxide (also referred to as an oxide semiconductor) in its semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 19A and FIG. 19B.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided over and in contact with the semiconductor layer 321 and functions as a source electrode and a drain electrode.

In the case where the semiconductor layer 321 is an In—M—Zn oxide, examples of the atomic ratio of metal elements of a sputtering target used for depositing the In—M—Zn oxide include In:M:Zn=1:1:1, In:M:Zn=1:1:1.2, In:M:Zn=1:3:2, In:M:Zn=1:3:4, In:M:Zn=1:3:6, In:M:Zn=2:2:1, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5.

In addition, a target containing a polycrystalline oxide is preferably used as the sputtering target because formation of the semiconductor layer 321 having crystallinity is facilitated. Note that the atomic ratio in the semiconductor layer 321 to be deposited varies in the range of ±40% from the atomic ratio of the metal elements contained in the sputtering target. For example, in the case where the composition of a sputtering target used for the semiconductor layer 321 is In:Ga:Zn=4:2:4.1 [atomic ratio], the composition of the semiconductor layer 321 to be deposited is in the neighborhood of In:Ga:Zn=4:2:3 [atomic ratio] in some cases.

In addition, the energy gap of the semiconductor layer 321 is greater than or equal to 2 eV, preferably greater than or equal to 2.5 eV. With the use of such a metal oxide having a wider energy gap than silicon, the off-state current of the transistor can be reduced.

Furthermore, the semiconductor layer 321 preferably has a non-single-crystal structure. Examples of the non-single-crystal structure include a CAAC structure to be described later, a polycrystalline structure, a microcrystalline structure, and an amorphous structure. Among the non-single-crystal structures, the amorphous structure has the highest density of defect states, whereas the CAAC structure has the lowest density of defect states.

A CAAC (c-axis aligned crystal) will be described below. A CAAC refers to an example of a crystal structure.

The CAAC structure is a crystal structure of a thin film or the like that has a plurality of nanocrystals (crystal regions having a maximum diameter of less than 10 nm), characterized in that the nanocrystals each have c-axis alignment in a particular direction, the nanocrystals each have neither a-axis alignment nor b-axis alignment, and the nanocrystals have continuous crystal connection in the a-axis and b-axis directions without forming a grain boundary. In particular, a thin film having the CAAC structure is characterized in that the c-axes of nanocrystals are likely to be aligned in a film thickness direction, a normal direction of a surface where the thin film is formed, or a normal direction of a surface of the thin film.

A CAAC-OS (Oxide Semiconductor) is an oxide semiconductor with high crystallinity. Meanwhile, in the CAAC-OS, it can be said that a reduction in electron mobility due to the crystal grain boundary is less likely to occur because a clear crystal grain boundary cannot be observed. Moreover, since the crystallinity of an oxide semiconductor might be decreased by entry of impurities, formation of defects, or the like, the CAAC-OS can also be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability.

Here, in crystallography, in a unit cell formed with three axes (crystal axes) of the a-axis, the b-axis, and the c-axis, a specific axis is generally taken as the c-axis in the unit cell. In particular, in the case of a crystal having a layered structure, two axes parallel to the plane direction of a layer are regarded as the a-axis and the b-axis and an axis intersecting with the layer is regarded as the c-axis in general. Typical examples of such a crystal having a layered structure include graphite, which is classified as a hexagonal system. In a unit cell of graphite, the a-axis and the b-axis are parallel to a cleavage plane and the c-axis is orthogonal to the cleavage plane. For example, an InGaZnO₄ crystal having a YbFe₂O₄ type crystal structure, which is a layered structure, can be classified as a hexagonal system, and in a unit cell thereof, the a-axis and the b-axis are parallel to the plane direction of a layer and the c-axis is orthogonal to the layer (i.e., the a-axis and the b-axis).

In an image observed with a TEM, crystal parts cannot be found clearly in an oxide semiconductor film having a microcrystalline structure (a microcrystalline oxide semiconductor film) in some cases. In most cases, the size of a crystal part included in the microcrystalline oxide semiconductor film is greater than or equal to 1 nm and less than or equal to 100 nm, or greater than or equal to 1 nm and less than or equal to 10 nm. In particular, an oxide semiconductor film including a nanocrystal (nc) that is a microcrystal with a size greater than or equal to 1 nm and less than or equal to 10 nm, or greater than or equal to 1 nm and less than or equal to 3 nm is referred to as an nc-OS (nanocrystalline Oxide Semiconductor) film. In addition, in an image observed with a TEM, for example, a crystal grain boundary cannot be found clearly in the nc-OS film in some cases.

In the nc-OS film, a microscopic region (e.g., a region greater than or equal to 1 nm and less than or equal to 10 nm, in particular, a region greater than or equal to 1 nm and less than or equal to 3 nm) has periodic atomic arrangement. In addition, there is no regularity of crystal orientation between different crystal parts in the nc-OS film. Thus, the orientation in the whole film is not observed. Accordingly, in some cases, the nc-OS film cannot be distinguished from an amorphous oxide semiconductor film depending on an analysis method. For example, when the nc-OS film is subjected to structural analysis by an out-of-plane method with an XRD apparatus using an X-ray having a diameter larger than the size of a crystal part, a peak that shows a crystal plane is not detected. Furthermore, a diffraction pattern like a halo pattern is observed when the nc-OS film is subjected to electron diffraction (also referred to as selected-area electron diffraction) using an electron beam with a probe diameter larger than the diameter of a crystal part (e.g., larger than or equal to 50 nm). Meanwhile, in some cases, a circular (ring-like) region with high luminance is observed when the nc-OS film is subjected to electron diffraction (also referred to as nanobeam electron diffraction) using an electron beam with a probe diameter close to or smaller than the diameter of a crystal part (e.g., larger than or equal to 1 nm and smaller than or equal to 30 nm), and spots are observed in the ring-like region.

The nc-OS film has a lower density of defect states than the amorphous oxide semiconductor film. Note that there is no regularity of crystal orientation between different crystal parts in the nc-OS film. Thus, the nc-OS film has a higher density of defect states than the CAAC-OS film. Therefore, the nc-OS film has a higher carrier density and higher electron mobility than the CAAC-OS film in some cases. Accordingly, a transistor using the nc-OS film might exhibit a high field-effect mobility.

The nc-OS film can be formed at a smaller oxygen flow rate ratio in deposition than the CAAC-OS film. The nc-OS film can be also formed at a lower substrate temperature in deposition than the CAAC-OS film. For example, the nc-OS film can be deposited at a comparatively low substrate temperature (e.g., a temperature lower than or equal to 130° C.) or without heating of the substrate and thus is suitable for the case of using a large glass substrate, a resin substrate, or the like, and productivity can be increased.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with the top surface of the semiconductor layer 321 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so as to be level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water or hydrogen from the insulating layer 265 or the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a covering the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

### [Display Device 200E]

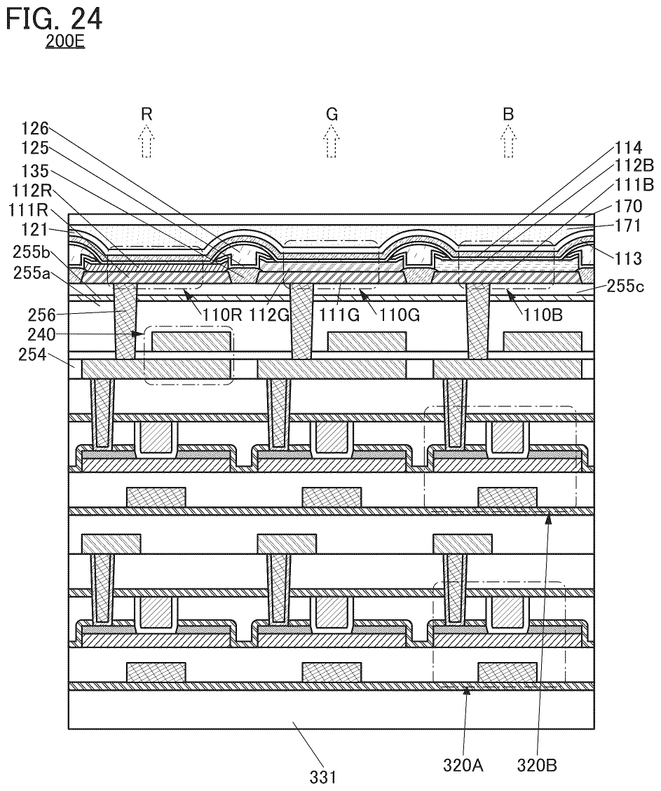

The display device 200E illustrated in FIG. 24 has a structure in which a transistor 320A and a transistor 320B each including an oxide semiconductor in a semiconductor where a channel is formed are stacked.

The display device 200D can be referred to for the structure of the transistor 320A, the transistor 320B, and other peripheral structures.

Note that although the structure where two transistors including an oxide semiconductor are stacked is described here, the present invention is not limited thereto. For example, three or more transistors may be stacked.

### [Display Device 200F]

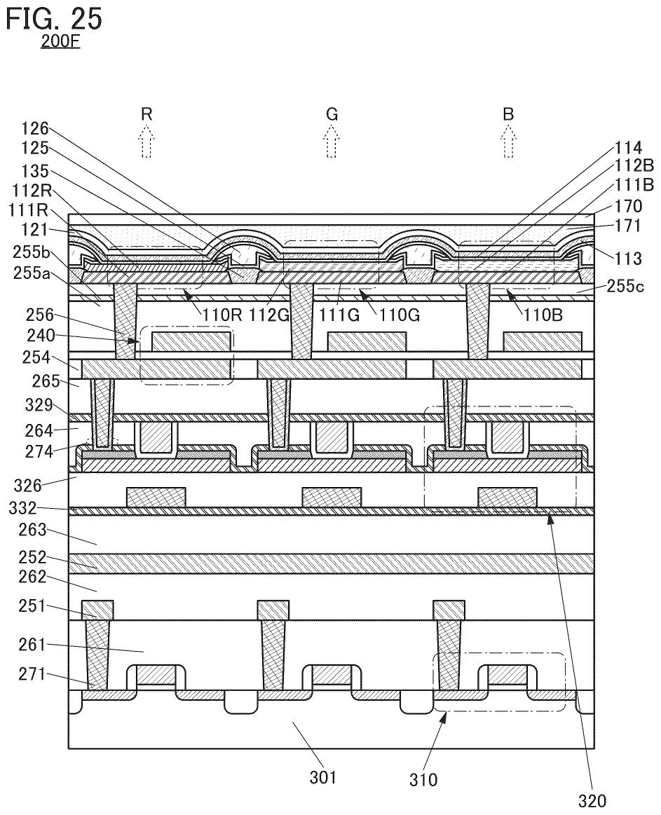

The display device 200F illustrated in FIG. 25 has a structure in which the transistor 310 whose channel is formed in the substrate 301 and the transistor 320 including a metal oxide in the semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display panel can be downsized as compared with the case where a driver circuit is provided around a display region.

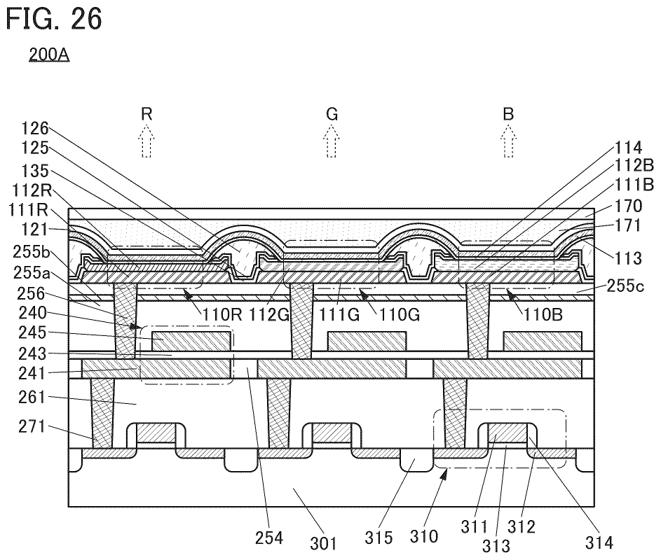

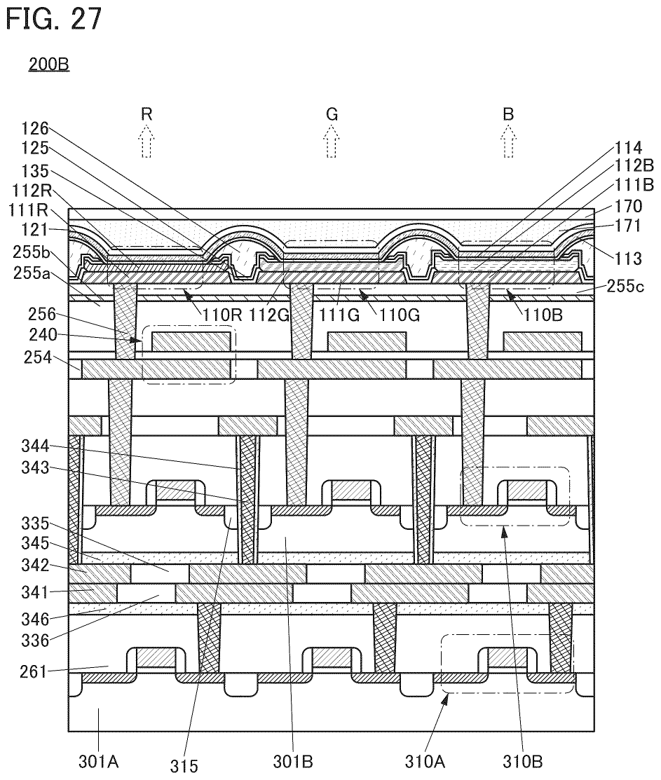

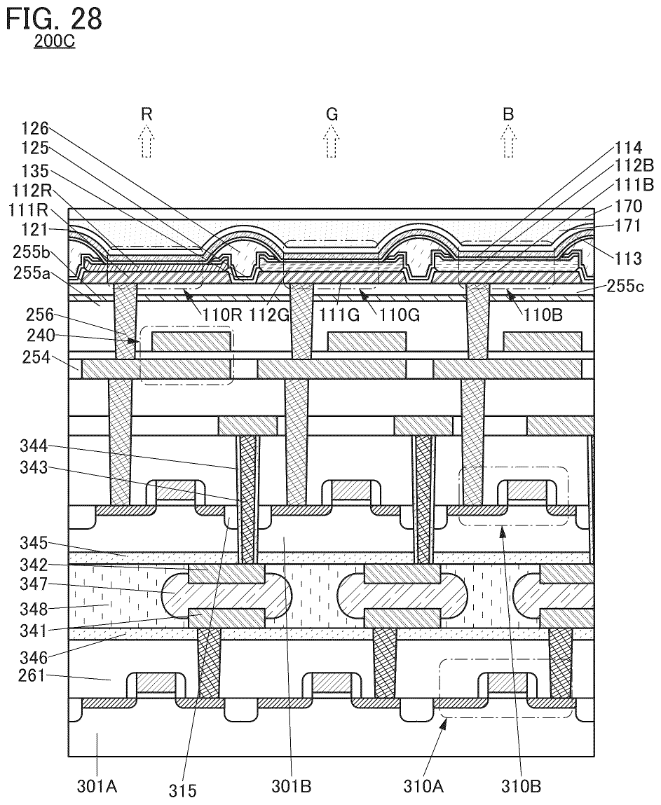

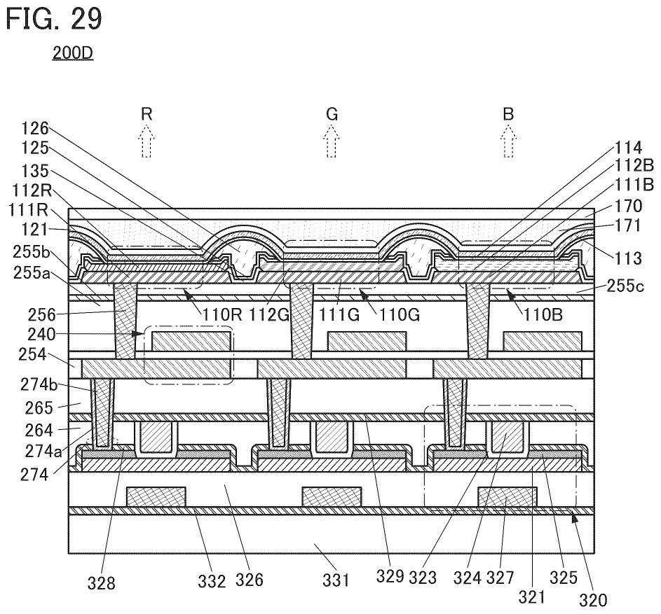

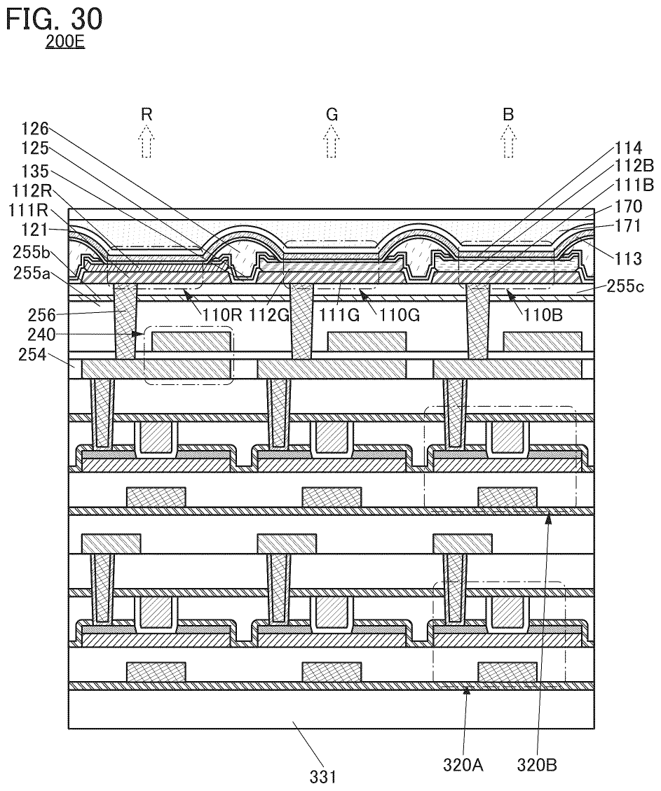

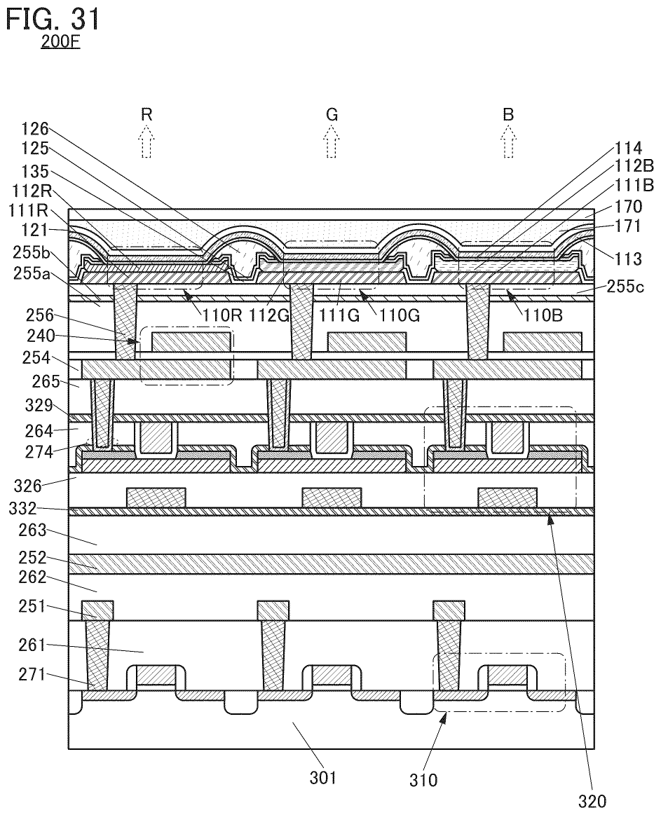

Although FIG. 20 to FIG. 25 illustrate examples in which an organic resin is used for the insulating layer 135, an inorganic insulating material may also be used. FIG. 26 to FIG. 31 illustrate examples in which an inorganic insulating material is used for the insulating layer 135.

At least part of this embodiment can be implemented in combination with the other embodiments described in this specification as appropriate.

### EMBODIMENT 4

In this embodiment, a light-emitting element (also referred to as a light-emitting device) that can be used in the display device of one embodiment of the present invention will be described.

In this specification and the like, a light-emitting device (also referred to as a light-emitting element) includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a device formed using a metal mask or an FMM (a fine metal mask or a high-resolution metal mask) may be referred to as a device having an MM (metal mask) structure. In this specification and the like, a device formed without using a metal mask or an FMM may be referred to as a device having an MML (metal maskless) structure.

In this specification and the like, a structure where light-emitting layers in light-emitting devices of different colors (here, blue (B), green (G), and red (R)) are separately formed or separately patterned is sometimes referred to as an SBS (Side By Side) structure. The SBS structure can optimize materials and structures of light-emitting devices and thus can extend the freedom of choice of materials and structures, whereby the luminance and the reliability can be easily improved. In this specification and the like, a light-emitting device capable of emitting white light may be referred to as a white-light-emitting device. Note that a combination of white-light-emitting devices with coloring layers (e.g., color filters) enables a full-color display device.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from one another on the basis of the cross-sectional shape, properties, or the like in some cases. One layer may have two or three functions of the carrier-injection layer, the carrier-transport layer, and the carrier-blocking layer in some cases.

### [Light-Emitting Device]

Structures of light-emitting devices can be classified roughly into a single structure and a tandem structure. A device with a single structure includes one light-emitting unit between a pair of electrodes. The light-emitting unit includes one or more light-emitting layers. To obtain white light emission with a single structure, two or more light-emitting layers are selected so that a white color can be produced by light emission of the light-emitting layers. For example, when two colors are used, by making the emission color of a first light-emitting layer and the emission color of a second light-emitting layer complementary colors, the light-emitting device can be configured to emit white light as a whole. To obtain white light emission by using three or more light-emitting layers, the light-emitting device is configured to emit white light as a whole by combining emission colors of the three or more light-emitting layers.

A light-emitting device with a tandem structure includes a plurality of light-emitting units between a pair of electrodes. Each light-emitting unit includes one or more light-emitting layers. When light-emitting layers that emit light of the same color are used in each light-emitting unit, luminance per predetermined current can be increased, and the light-emitting device can have higher reliability than that with a single structure. To obtain white light emission with a tandem structure, the structure is made so that light from light-emitting layers of the plurality of light-emitting units can be combined to be white light. Note that a combination of emission colors for obtaining white light emission is similar to that in the case of a single structure. In the device with a tandem structure, an intermediate layer such as a charge-generation layer is suitably provided between the plurality of light-emitting units.

When a white-light-emitting device and a light-emitting device with an SBS structure are compared with each other, the light-emitting device with the SBS structure can have lower power consumption than the white-light-emitting device. Meanwhile, the white-light-emitting device can achieve lower manufacturing cost and a higher manufacturing yield because the manufacturing process of the white-light-emitting device is simpler than that of the light-emitting device with the SBS structure.

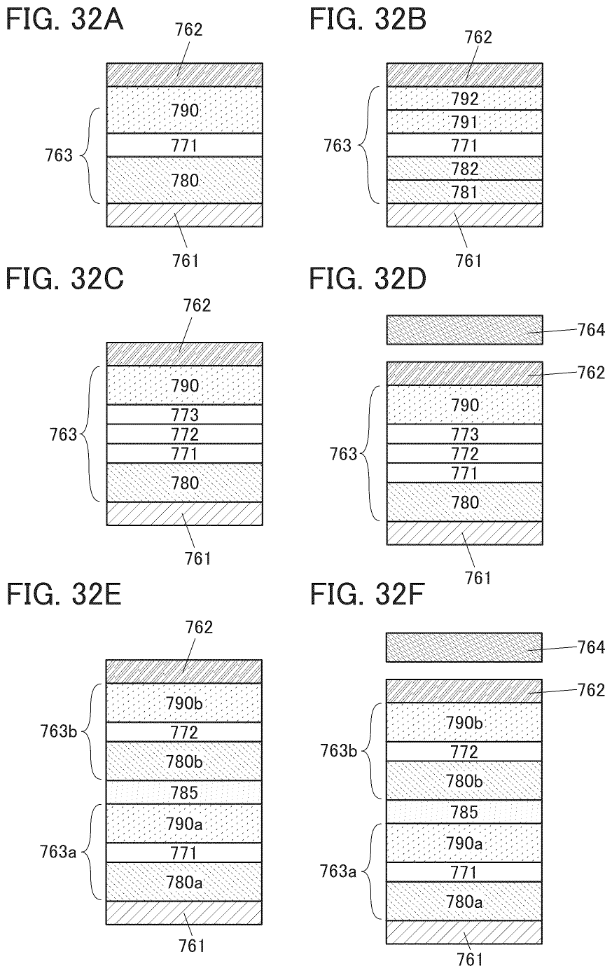

As illustrated in FIG. 32A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 32A is referred to as a single structure in this specification.

FIG. 32B is a modification example of the EL layer 763 included in the light-emitting device illustrated in FIG. 32A. Specifically, the light-emitting device illustrated in FIG. 32B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layers 771, 772, and 773) are provided between the layer 780 and the layer 790 as illustrated in FIG. 32C and FIG. 32D are other variations of the single structure. Although FIG. 32C and FIG. 32D illustrate the examples where three light-emitting layers are included, the light-emitting layer in the light-emitting device with a single structure may include two or four or more light-emitting layers.

In addition, the light-emitting device with a single structure may include a buffer layer between two light-emitting layers. The buffer layer can be formed using a material that can be used for the hole-transport layer or the electron-transport layer, for example.

A structure where a plurality of light-emitting units (a light-emitting unit 763a and a light-emitting unit 763b) are connected in series with a charge-generation layer 785 (also referred to as an intermediate layer) therebetween as illustrated in FIG. 32E and FIG. 32F is referred to as a tandem structure in this specification. Note that a tandem structure may be referred to as a stack structure. The tandem structure enables a light-emitting device capable of high-luminance light emission. Furthermore, the tandem structure can reduce the amount of current needed for obtaining the same luminance as compared with a single structure, and thus can improve the reliability.

Note that FIG. 32D and FIG. 32F illustrate examples where the display device includes a layer 764 overlapping with the light-emitting device. FIG. 32D illustrates an example where the layer 764 overlaps with the light-emitting device illustrated in FIG. 32C, and FIG. 32F illustrates an example where the layer 764 overlaps with the light-emitting device illustrated in FIG. 32E. In FIG. 32D and FIG. 32F, a conductive film transmitting visible light is used for the upper electrode 762 to extract light to the upper electrode 762 side.

One or both of a color conversion layer and a color filter (a coloring layer) can be used as the layer 764.

In FIG. 32C and FIG. 32D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 32D, blue light emitted from the light-emitting device can be converted into light with a longer wavelength, and red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIG. 32C and FIG. 32D, light-emitting substances that emit light of different colors may be used for the light-emitting layer 771, the light-emitting layer 772, and the light-emitting layer 773. White light can be obtained when the light-emitting layer 771, the light-emitting layer 772, and the light-emitting layer 773 emit light of complementary colors. The light-emitting device with a single structure preferably includes a light-emitting layer containing a light-emitting substance emitting blue light and a light-emitting layer containing a light-emitting substance emitting visible light with a longer wavelength than blue light, for example.

A color filter may be provided as the layer 764 illustrated in FIG. 32D. When white light passes through the color filter, light of a desired color can be obtained.

In the case where the light-emitting device with a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB from an anode side or RBG from an anode side, for example. In that case, a buffer layer may be provided between R and G or between R and B.

For example, in the case where the light-emitting device with a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

In the light-emitting device that emits white light, two or more kinds of light-emitting substances are preferably included. To obtain white light emission, two or more kinds of light-emitting substances are selected such that achromatic color is obtained by their light emission. For example, in the case of two colors, emission colors of a first light-emitting layer and a second light-emitting layer are complementary colors, whereby the light-emitting device can emit white light as a whole. Furthermore, in the case where white light emission is obtained using three or more light-emitting layers, the light-emitting device is configured to be able to emit white light as a whole by combining the emission colors of the three or more light-emitting layers.

Also in FIG. 32C and FIG. 32D, the layer 780 and the layer 790 may each independently have a stacked-layer structure of two or more layers as illustrated in FIG. 32B.

In FIG. 32E and FIG. 32F, light-emitting substances that emit light of the same color, or moreover, the same light-emitting substance may be used for the light-emitting layer 771 and the light-emitting layer 772. For example, in light-emitting devices included in subpixels that emit light of different colors, a light-emitting substance that emits blue light may be used for each of the light-emitting layer 771 and the light-emitting layer 772. In the subpixel that emits blue light, blue light emitted from the light-emitting device can be extracted. In the subpixel that emits red light and the subpixel that emits green light, by providing a color conversion layer as the layer 764 illustrated in FIG. 32F, blue light emitted from the light-emitting device can be converted into light with a longer wavelength, and red light or green light can be extracted. As the layer 764, both a color conversion layer and a coloring layer are preferably used.

In FIG. 32E and FIG. 32F, light-emitting substances that emit light of different colors may be used for the light-emitting layer 771 and the light-emitting layer 772. When the light-emitting layer 771 and the light-emitting layer 772 emit light of complementary colors, white light emission can be obtained. A color filter may be provided as the layer 764 illustrated in FIG. 32F. When white light passes through the color filter, light of a desired color can be obtained.

Although FIG. 32E and FIG. 32F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 32E and FIG. 32F illustrate the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 32E and FIG. 32F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing a light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

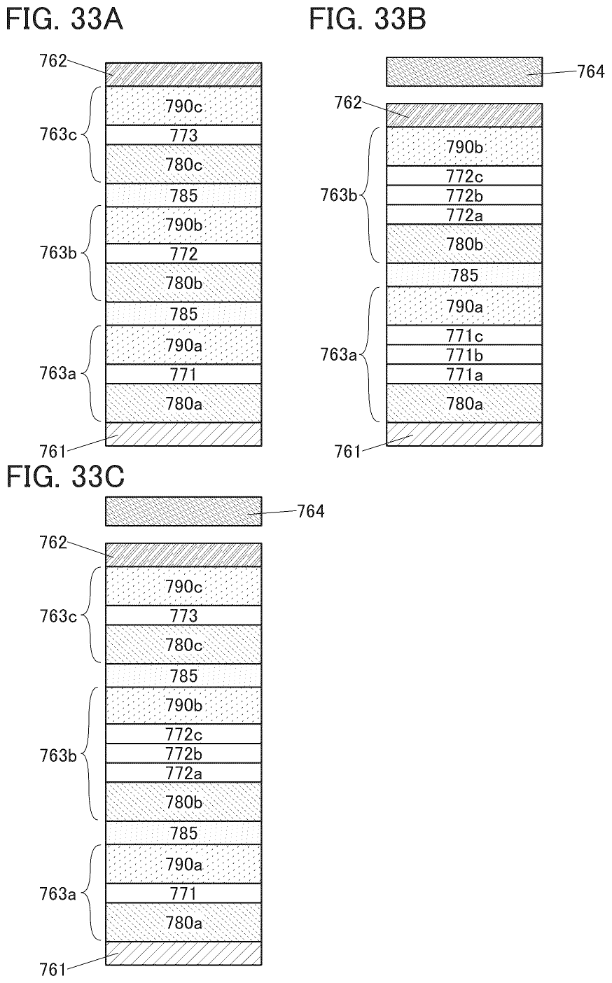

Structures illustrated in FIG. 33A to FIG. 33C can be given as examples of the light-emitting device with a tandem structure.

FIG. 33A illustrates a structure including three light-emitting units. In FIG. 33A, a plurality of light-emitting units (the light-emitting unit 763a, the light-emitting unit 763b, and a light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 33A, the light-emitting layer 771, the light-emitting layer 772, and the light-emitting layer 773 can contain light-emitting substances that emit light of the same color. Specifically, the light-emitting layer 771, the light-emitting layer 772, and the light-emitting layer 773 can each have a structure containing a blue (B) light-emitting substance (i.e., a three-unit tandem structure of B\B\B). Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 33A, light-emitting substances with different emission colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting device with a tandem structure may be employed in which light-emitting units each including a plurality of light-emitting layers are stacked as illustrated in FIG. 33B. FIG. 33B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 33B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 33B is a two-unit tandem structure of WWW. Note that there is no particular limitation on the stacking order of the light-emitting substances having complementary emission colors. The practitioner can select the optimal stacking order as appropriate. Although not illustrated, a three-unit tandem structure of W\W\W or a tandem structure with four or more units may be employed.

In the case where the light-emitting device with a tandem structure is used, the following structure can be given: a B\Y or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order, for example. Note that “a\b” means that one light-emitting unit contains a light-emitting substance that emits light of a and a light-emitting substance that emits light of b.

As illustrated in FIG. 33C, a light-emitting unit including one light-emitting layer and a light-emitting unit including a plurality of light-emitting layers may be used in combination.

Specifically, in the structure illustrated in FIG. 33C, a plurality of light-emitting units (the light-emitting unit 763a, the light-emitting unit 763b, and the light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 33C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where a display device includes a light-emitting device emitting infrared light, it is preferable that a conductive film transmitting visible light and infrared light be used for the electrode through which light is extracted, and a conductive film reflecting visible light and infrared light be used for the electrode through which light is not extracted.

A conductive film transmitting visible light may be used also for an electrode through which no light is extracted. In this case, this electrode is preferably provided between the reflective layer and the EL layer 763. In other words, light emitted from the EL layer 763 may be reflected by the reflective layer to be extracted from the display device.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Therefore, one of the pair of electrodes included in the light-emitting device preferably includes an electrode having properties of transmitting and reflecting visible light (a transflective electrode), and the other preferably includes an electrode having a property of reflecting visible light (a reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with a wavelength longer than or equal to 400 nm and shorter than 750 nm) transmittance higher than or equal to 40% is preferably used as the transparent electrode of the light-emitting device. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower.

The light-emitting device includes at least the light-emitting layer. In addition, the light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting device, and an inorganic compound may also be included. Each layer included in the light-emitting device can be formed by a method such as an evaporation method (including a vacuum evaporation method), a transfer method, a printing method, an inkjet method, or a coating method.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, a substance that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property which can be used for the hole-transport layer and will be described later. As the electron-transport material, it is possible to use a material with a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer injecting holes from an anode to a hole-transport layer and containing a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, an oxide of a metal belonging to any of Group 4 to Group 8 of the periodic table can be used, for example. Specifically, molybdenum oxide, vanadium oxide, niobium oxide, tantalum oxide, chromium oxide, tungsten oxide, manganese oxide, and rhenium oxide are given. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material having a high hole-injection property, a material that contains a hole-transport material and the above-described oxide of a metal belonging to any of Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material with a high hole-transport property such as a T-electron rich heteroaromatic compound (e.g., a carbazole derivative, a thiophene derivative, or a furan derivative) or an aromatic amine (a compound having an aromatic amine skeleton) is preferable.

The electron-blocking layer is provided in contact with the light-emitting layer. The electron-blocking layer is a layer having a hole-transport property and containing a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a T-electron deficient heteroaromatic compound including a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the LUMO level of the material with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFx, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used for the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer containing a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can suppress an increase in driving voltage.

At least part of this embodiment can be implemented in combination with the other embodiments described in this specification as appropriate.

### EMBODIMENT 5

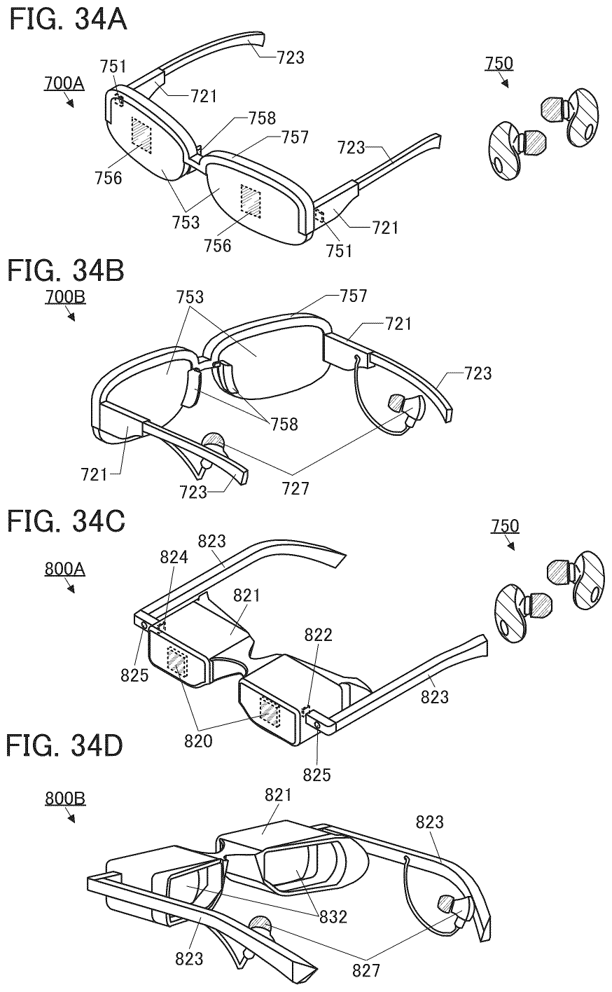

In this embodiment, electronic devices according to one embodiment of the present invention will be described using FIG. 34 to FIG. 36.

Electronic devices in this embodiment each include the display panel (display device) according to one embodiment of the present invention in a display portion. The display panel according to one embodiment of the present invention can easily achieve higher resolution and higher definition and can achieve high display quality. Thus, the display device according to one embodiment of the present invention can be used for display portions of a variety of electronic devices.

Examples of the electronic devices include a digital camera, a digital video camera, a digital photo frame, a cellular phone, a portable game machine, a portable information terminal, and an audio reproducing device, in addition to electronic devices with comparatively large screens, such as a television device, a desktop or laptop personal computer, a monitor for a computer or the like, digital signage, and a large game machine such as a pachinko machine.

In particular, the display panel according to one embodiment of the present invention can have higher resolution, and thus can be suitably used for an electronic device having a comparatively small display portion. Examples of such an electronic device include wristwatch-type and bracelet-type information terminal devices (wearable devices) and a wearable device that can be worn on a head, such as a device for VR such as a head-mounted display, a glasses-type device for AR, or a device for MR.

The definition of the display panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. In addition, the pixel density (resolution) of the display panel of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display panel having one or both of high definition and high resolution, realistic sensation, sense of depth, and the like can be further increased. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a storage medium.

Examples of wearable devices that can be worn on a head are described using FIG. 34A to FIG. 34D. These wearable devices have one or both of a function of displaying AR contents and a function of displaying VR contents. Note that the wearable devices may have a function of displaying SR or MR contents, in addition to AR and VR contents. The electronic device having a function of displaying contents of at least one of AR, VR, SR, MR, and the like enables the user to reach a higher level of immersion.

An electronic device 700A illustrated in FIG. 34A and an electronic device 700B illustrated in FIG. 34B each include a pair of display panels 751, a pair of housings 721, a communication portion (not illustrated), a pair of wearing portions 723, a control portion (not illustrated), an imaging portion (not illustrated), a pair of optical members 753, a frame 757, and a pair of nose pads 758.

The display panel according to one embodiment of the present invention can be employed for the display panel 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, the user can see images displayed on the display regions that are superimposed on transmission images seen through the optical members 753. Thus, the electronic device 700A and the electronic device 700B are electronic devices capable of AR display.

In each of the electronic device 700A and the electronic device 700B, a camera capable of capturing images of the front side may be provided as the imaging portion. Furthermore, when each of the electronic device 700A and the electronic device 700B is provided with an acceleration sensor such as a gyroscope sensor, the orientation of a user's head can be sensed and an image corresponding to the orientation can be displayed on the display region 756.

The communication portion includes a wireless communication device, and a video signal and the like can be supplied by the wireless communication device. Note that instead of the wireless communication device or in addition to the wireless communication device, a connector to which a cable supplied with a video signal and a power potential can be connected may be provided.

In addition, each of the electronic device 700A and the electronic device 700B is provided with a battery so that charging can be performed wirelessly and/or by wire.

A touch sensor module may be provided in the housing 721. The touch sensor module has a function of detecting a touch on an outer surface of the housing 721. A tap operation, a slide operation, or the like by the user can be detected with the touch sensor module, so that a variety of processing can be executed. For example, processing such as a pause or a restart of a moving image can be executed by a tap operation, and processing such as fast forward or fast rewind can be executed by a slide operation. In addition, the touch sensor module is provided in each of the two housings 721, so that the range of the operation can be increased.

A variety of touch sensors can be employed for the touch sensor module. For example, touch sensors of a variety of types such as a capacitive type, a resistive film type, an infrared type, an electromagnetic induction type, a surface acoustic wave type, and an optical type can be employed. In particular, a capacitive sensor or an optical sensor is preferably employed for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 34C and an electronic device 800B illustrated in FIG. 34D each include a pair of display portions 820, a housing 821, a communication portion 822, a pair of wearing portions 823, a control portion 824, a pair of imaging portions 825, and a pair of lenses 832.

The display panel according to one embodiment of the present invention can be employed in the display portion 820. Thus, the electronic device can perform display with extremely high resolution. This enables the user to feel a high sense of immersion.

The display portions 820 are positioned inside the housing 821 so as to be seen through the lenses 832. Furthermore, when the pair of display portions 820 display different images, 3D display using parallax can be also performed.

Each of the electronic device 800A and the electronic device 800B can be regarded as an electronic device for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lens 832 and the display portion 820 is preferably included.

The electronic device 800A or the electronic device 800B can be worn on the user's head with the wearing portions 823. Note that FIG. 34C and the like illustrate examples where the wearing portion 823 has a shape like an ear piece of glasses (also referred to as a temple or the like); however, one embodiment of the present invention is not limited thereto. The wearing portion 823 can have any shape with which the user can wear and can have a shape of a helmet or a band, for example.

The imaging portion 825 has a function of obtaining external information. Data obtained by the imaging portion 825 can be output to the display portion 820. An image sensor can be used for the imaging portion 825. Moreover, a plurality of cameras may be provided to support a plurality of fields of view, such as a telescope field of view and a wide field of view.

Note that although an example where the imaging portion 825 is included is shown here, a range sensor that is capable of measuring the distance between the user and an object (hereinafter such a sensor is also referred to as a sensing portion) is provided. In other words, the imaging portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more information can be obtained and a gesture operation with higher accuracy is possible.

The electronic device 800A may include a vibration mechanism that functions as bone-conduction earphones. For example, any one or more of the display portion 820, the housing 821, and the wearing portion 823 can include the vibration mechanism. Thus, without additionally requiring an audio device such as headphones, earphones, or a speaker, the user can enjoy a video and sound only by wearing the electronic device 800A.

The electronic device 800A and the electronic device 800B may each include an input terminal. To the input terminal, a cable for supplying a video signal from a video output device or the like, power for charging a battery provided in the electronic device, and the like can be connected.

An electronic device according to one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 34A has a function of transmitting information to the earphones 750 with the wireless communication function. As another example, the electronic device 800A illustrated in FIG. 34C has a function of transmitting information to the earphones 750 with the wireless communication function.

Alternatively, the electronic device may include an earphone portion. The electronic device 700B illustrated in FIG. 34B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic device 800B illustrated in FIG. 34D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. Alternatively, the electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (the electronic device 700A, the electronic device 700B, or the like) and the goggles-type device (the electronic device 800A, the electronic device 800B, or the like) are suitable for the electronic device according to one embodiment of the present invention.

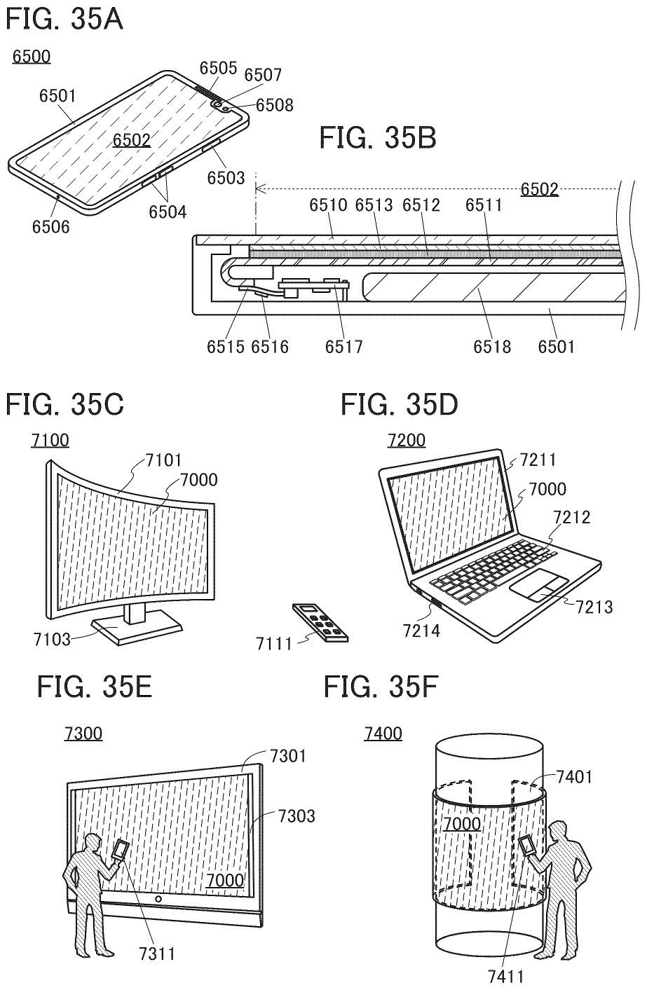

An electronic device 6500 illustrated in FIG. 35A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel according to one embodiment of the present invention can be employed for the display portion 6502.

FIG. 35B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display according to one embodiment of the present invention can be employed for the display panel 6511. Thus, an extremely lightweight electronic device can be achieved. In addition, since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of a pixel portion, so that an electronic device with a narrow bezel can be achieved.

FIG. 35C illustrates an example of a television device. In a television device 7100, a display portion 7000 is incorporated in a housing 7101. Here, a structure in which the housing 7101 is supported by a stand 7103 is illustrated.

Operations of the television device 7100 illustrated in FIG. 35C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and sound volume can be operated and a video displayed on the display portion 7000 can be operated.

Note that the television device 7100 includes a receiver, a modem, and the like. A general television broadcast can be received with the receiver. In addition, when the television device is connected to a communication network with or without wires via the modem, one-way (from a transmitter to a receiver) or two-way (between a transmitter and a receiver or between receivers, for example) data communication can be performed.

FIG. 35D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

FIG. 35E and FIG. 35F illustrate examples of digital signage.

Digital signage 7300 illustrated in FIG. 35E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 35F is digital signage 7400 attached to a cylindrical pillar 7401. The digital signage 7400 includes the display portion 7000 provided along a curved surface of the pillar 7401.

The larger display portion 7000 can increase the amount of information that can be provided at a time. In addition, the larger display portion 7000 attracts more attention, so that advertising effects can be increased, for example.

The use of a touch panel in the display portion 7000 is preferable because in addition to display of an image or a moving image on the display portion 7000, an intuitive operation by the user is possible. Moreover, in the case where the display panel according to one embodiment of the present invention is used for providing information such as route information or traffic information, usability can be increased by an intuitive operation.

In addition, as illustrated in FIG. 35E and FIG. 35F, it is preferable that the digital signage 7300 or the digital signage 7400 can work with an information terminal device 7311 or an information terminal device 7411 such as a user's smartphone through wireless communication. For example, information of an advertisement displayed on the display portion 7000 can be displayed on a screen of the information terminal device 7311 or the information terminal device 7411. Furthermore, by the operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

The display panel according to one embodiment of the present invention can be employed for the display portion 7000 illustrated in each of FIG. 35C to FIG. 35F.

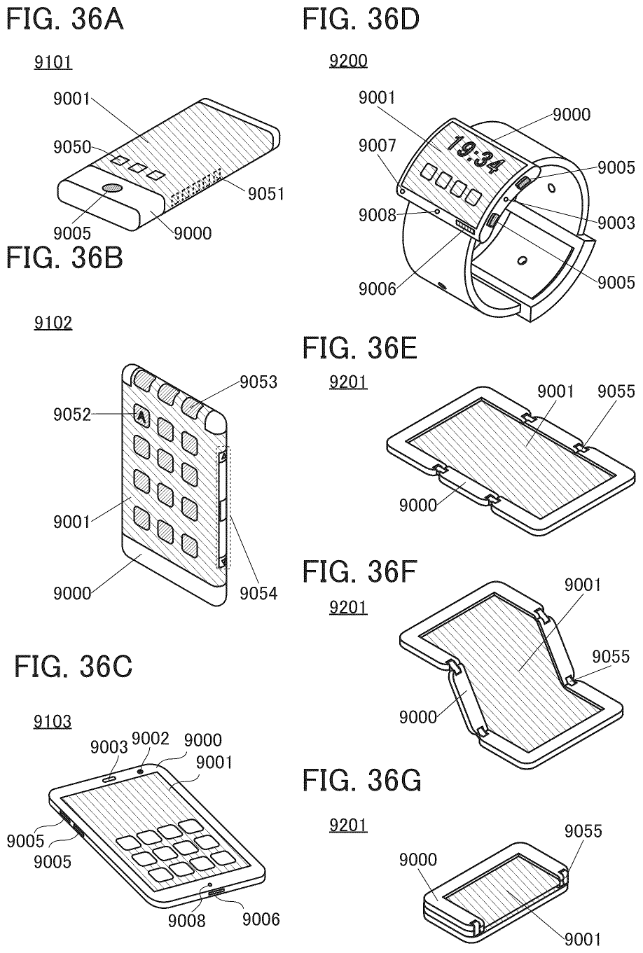

Electronic devices illustrated in FIG. 36A to FIG. 36G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, a distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic devices illustrated in FIG. 36A to FIG. 36G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a storage medium. Note that the functions of the electronic devices are not limited thereto, and the electronic devices can have a variety of functions. The electronic devices may include a plurality of display portions. In addition, the electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 36A to FIG. 36G are described in detail below.

FIG. 36A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. In addition, the portable information terminal 9101 can display characters and image information on its plurality of surfaces. FIG. 36A illustrates an example in which three icons 9050 are displayed. Furthermore, information 9051 indicated by dashed rectangles can be displayed on another surface of the display portion 9001. Examples of the information 9051 include notification of incoming e-mails, SNS, calls, and the like; the titles and senders of e-mails, SNS, and the like; dates; time; remaining battery; and radio field intensity. Alternatively, the icon 9050 or the like may be displayed at the position where the information 9051 is displayed.

FIG. 36B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, a user can check the information 9053 displayed in a position that can be observed from above the portable information terminal 9102, with the portable information terminal 9102 put in a breast pocket of his/her clothes. The user can see display without taking out the portable information terminal 9102 from the pocket and determine whether to answer a call, for example.

FIG. 36C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on a front surface of the housing 9000; the operation keys 9005 as buttons for operations on a left side surface of the housing 9000; and the connection terminal 9006 on a bottom surface.

FIG. 36D is a perspective view illustrating a wristwatch-type portable information terminal 9200. For example, the portable information terminal 9200 can be used as a Smartwatch (registered trademark). In addition, a display surface of the display portion 9001 is provided and curved, and display can be performed along the curved display surface. Furthermore, mutual communication between the portable information terminal 9200 and, for example, a headset capable of wireless communication enables hands-free calling. Moreover, with the connection terminal 9006, the portable information terminal 9200 can perform mutual data transmission with another information terminal and charging. Note that a charging operation may be performed by wireless power feeding.

FIG. 36E to FIG. 36G are perspective views illustrating a foldable portable information terminal 9201. In addition, FIG. 36E is a perspective view of an opened state of the portable information terminal 9201, FIG. 36G is a perspective view of a folded state thereof, and FIG. 36F is a perspective view of a state in the middle of change from one of FIG. 36E and FIG. 36G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature greater than or equal to 0.1 mm and less than or equal to 150 mm.

At least part of this embodiment can be implemented in combination with the other embodiments described in this specification as appropriate.

### REFERENCE NUMERALS

100: display device, 101: substrate, 103: insulating layer, 104: functional layer, 110a: light-emitting element, 110B: light-emitting element, 110b: light-emitting element, 110c: light-emitting element, 110d: light-emitting element, 110e: light-emitting element, 110G: light-emitting element, 110R: light-emitting element, 110: pixel, 111B: pixel electrode, 111C: connection electrode, 111G: pixel electrode, 111R: pixel electrode, 111: pixel electrode, 112B: EL layer, 112Bf: EL film, 112G: EL layer, 112Gf: EL film, 112R: EL layer, 112Rf: EL film, 112: EL layer, 113: common electrode, 114: common layer, 118: insulating layer, 120: substrate, 121: protective layer, 122: adhesive layer, 123: planarization layer, 124a: pixel, 124b: pixel, 124: planarization layer, 125f: insulating film, 125: insulating layer, 126f: resin film, 126: organic layer, resin layer, 135a: insulating layer, 135b: insulating layer, 135f: insulating film, 135: insulating layer, 140: connection portion, 143a: resist mask, 143b: resist mask, 143c: resist mask, 144a: sacrificial film, 144b: sacrificial film, 144c: sacrificial film, 145a: sacrificial layer, 145b: sacrificial layer, 145c: sacrificial layer, 145: sacrificial layer, 146a: sacrificial film, 146b: sacrificial film, 146c: sacrificial film, 147a: sacrificial layer, 147b: sacrificial layer, 147c: sacrificial layer, 150B: light-emitting element, 150G: light-emitting element, 150R: light-emitting element, 150: pixel, 170: substrate, 171: adhesive layer, 174B: coloring layer, 174G: coloring layer, 174R: coloring layer, 176: lens array, 200A: display device, 200B: display device, 200C: display device, 200D: display device, 200E: display device, 200F: display device, 240: capacitor, 241: conductive layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: imaging portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal device, 7400: digital signage, 7401: pillar, 7411: information terminal device, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A manufacturing method of a display device, comprising the steps of:
forming a first pixel electrode and a second pixel electrode;
forming a first insulating layer covering an end portion of the first pixel electrode and an end portion of the second pixel electrode and overlapping with a region sandwiched between the first pixel electrode and the second pixel electrode;
forming a first film over the first pixel electrode, the second pixel electrode, and the first insulating layer;
forming a first sacrificial film over the first film;
removing part of the first film and part of the first sacrificial film to form a first layer and a first sacrificial layer overlapping with part of the first insulating layer and the first pixel electrode and expose another part of the first insulating layer and the second pixel electrode;
forming a second film over the first sacrificial layer, the second pixel electrode, and the first insulating layer;
forming a second sacrificial film over the second film;
removing part of the second film and part of the second sacrificial film to form a second layer and a second sacrificial layer overlapping with the another part of the first insulating layer and the second pixel electrode and expose the first sacrificial layer;
forming a second insulating layer covering the first sacrificial layer, the second sacrificial layer, and the first insulating layer;
forming a resin layer overlapping with the first insulating layer over the second insulating layer;
removing part of the first sacrificial layer, part of the second sacrificial layer, and part of the second insulating layer by etching using the resin layer as a mask to expose the first film and the second film; and
forming a common electrode to cover the first film, the second film, and the resin layer,
wherein the first film comprises a first light-emitting material that emits first light, and
wherein the second film comprises a second light-emitting material that emits second light of a color different from that of the first light.

2. The manufacturing method of the display device according to claim 1,
wherein the first insulating layer is formed using a photosensitive organic resin.

3. The manufacturing method of the display device according to claim 2,
wherein the first insulating layer comprises one or more selected from an acrylic resin, a polyimide resin, an epoxy resin, a polyamide resin, a polyimide-amide resin, a siloxane resin, a benzocyclobutene-based resin, a phenol resin, and a precursor of any of these resins.

4. The manufacturing method of the display device according to claim 1,
wherein the first insulating layer is formed using an inorganic insulating material.

5. The manufacturing method of the display device according to claim 4,
wherein the first insulating layer comprises one or more selected from silicon oxide, silicon oxynitride, silicon nitride oxide, silicon nitride, aluminum oxide, aluminum oxynitride, and hafnium oxide.

6. A manufacturing method of a display device, comprising the steps of:
forming a first pixel electrode and a second pixel electrode;
forming a first insulating layer covering an end portion of the first pixel electrode and an end portion of the second pixel electrode and overlapping with a region sandwiched between the first pixel electrode and the second pixel electrode;
forming a first film over the first pixel electrode, the second pixel electrode, and the first insulating layer;
forming a first sacrificial film over the first film;
removing part of the first film and part of the first sacrificial film to form a first layer and a first sacrificial layer overlapping with part of the first insulating layer and the first pixel electrode and expose another part of the first insulating layer and the second pixel electrode;
forming a second film over the first sacrificial layer, the second pixel electrode, and the first insulating layer;
forming a second sacrificial film over the second film;
removing part of the second film and part of the second sacrificial film to form a second layer and a second sacrificial layer overlapping with the another part of the first insulating layer and the second pixel electrode and expose the first sacrificial layer;
forming a second insulating layer covering the first sacrificial layer, the second sacrificial layer, and the first insulating layer;
forming a resin layer overlapping with the first insulating layer over the second insulating layer;
removing part of the second insulating layer by etching using the resin layer as a mask and, after the removing, thinning the first sacrificial layer and the second sacrificial layer;
performing heat treatment;
removing part of the first sacrificial layer and part of the second sacrificial layer by etching using the resin layer as a mask to expose the first film and the second film; and
forming a common electrode to cover the first film, the second film, and the resin layer,
wherein the first film comprises a first light-emitting material that emits first light, and
wherein the second film comprises a second light-emitting material that emits second light of a color different from that of the first light.

7. The manufacturing method of the display device according to claim 6,
wherein the first insulating layer is formed using a photosensitive organic resin.

8. The manufacturing method of the display device according to claim 7,
wherein the first insulating layer comprises one or more selected from an acrylic resin, a polyimide resin, an epoxy resin, a polyamide resin, a polyimide-amide resin, a siloxane resin, a benzocyclobutene-based resin, a phenol resin, and a precursor of any of these resins.

9. The manufacturing method of the display device according to claim 6,
wherein the first insulating layer is formed using an inorganic insulating layer.

10. The manufacturing method of the display device according to claim 9,
wherein the first insulating layer comprises one or more selected from silicon oxide, silicon oxynitride, silicon nitride oxide, silicon nitride, aluminum oxide, aluminum oxynitride, and hafnium oxide.

11. The manufacturing method of the display device according to claim 6,
wherein the heat treatment is performed at a temperature of higher than or equal to 50° C. and lower than or equal to 200° C.

12. The manufacturing method of the display device according to claim 6,
wherein the resin layer is changed in shape by the heat treatment.

13. The manufacturing method of the display device according to claim 1,
wherein the first sacrificial film, the second sacrificial film, and the second insulating layer are etched by wet etching.

14. The manufacturing method of the display device according to claim 1,
wherein the first sacrificial film, the second sacrificial film, and the second insulating layer are formed by an atomic layer deposition method.

15. The manufacturing method of the display device according to claim 1,
wherein the first sacrificial film, the second sacrificial film, and the second insulating layer comprise aluminum oxide.

16. The manufacturing method of the display device according to claim 1,
wherein the first light is blue, and
wherein the second light is green or red.

17. The manufacturing method of the display device according to claim 6,
wherein the first sacrificial film, the second sacrificial film, and the second insulating layer are etched by wet etching.

18. The manufacturing method of the display device according to claim 6,
wherein the first sacrificial film, the second sacrificial film, and the second insulating layer are formed by an atomic layer deposition method.

19. The manufacturing method of the display device according to claim 6,
wherein the first sacrificial film, the second sacrificial film, and the second insulating layer comprise aluminum oxide.

20. The manufacturing method of the display device according to claim 6,
wherein the first light is blue, and
wherein the second light is green or red.
